(19) United States
(12) Patent Application Publication
(10) Pub. No.: US 2017/0133399 A1
(43) Pub. Date: May 11, 2017

(54) MEMORY DEVICE AND METHOD OF MANUFACTURING THE SAME

(71) Applicants: Ki Jeong KIM, Hwaseong-si (KR); Byoung Jun CHOI, Hwaseong-si (KR); O Ik KWON, Yongin-si (KR)

(72) Inventors: Ki Jeong KIM, Hwaseong-si (KR); Byoung Jun CHOI, Hwaseong-si (KR); O Ik KWON, Yongin-si (KR)

(21) Appl. No.: 15/222,374

(22) Filed: Jul. 28, 2016

(30) Foreign Application Priority Data
Nov. 10, 2015 (KR) 10-2015-0157636

(51) Int. Cl. H01L 27/115; H01L 29/66; H01L 23/535; H01L 29/792

(52) U.S. Cl. CPC H01L 27/11582; H01L 27/11556; H01L 29/7926; H01L 29/66833; H01L 23/535

(57) ABSTRACT

A memory device includes gate electrode layers stacked on top of each other on a substrate, a channel region on a cell region of the substrate and extending through the gate electrode layers in a direction perpendicular to an upper surface of the substrate, cell contacts connected to the gate electrode layers, an active region on a peripheral circuit region of the substrate, planar gate electrode layers on the peripheral circuit region and adjacent to the active region, a cover layer on the active region, and peripheral contacts connected to the active region and the planar gate electrode layers. At least a portion of the peripheral contacts are separated from the cover layer above the planar gate electrode layers.

### CROSS-REFERENCE TO RELATED APPLICATION(S)

This application claims priority under 35 U.S.C. §119 to Korean Patent Application No. 10-2015-0157636 filed on Nov. 10, 2015 in the Korean Intellectual Property Office, and the disclosure of which is incorporated herein by reference in its entirety.

### BACKGROUND

The present disclosure relates to a memory device and a method of manufacturing the same.

Volumes of electronic products have gradually been reduced, while being used to process high capacity data. Thus, the integration of semiconductor memory devices used in such electronic products is increasing. As a method in which the integration of semiconductor memory devices may be increased, a memory device having a vertical transistor structure rather than having an existing planar transistor structure has been proposed.

### SUMMARY

Example embodiments of inventive concepts relate to a memory device having a vertical structure in which a manufacturing process may be simplified and manufacturing costs may be reduced.

According to example embodiments of inventive concepts, a memory device may include a substrate including a cell region and a peripheral circuit region; a plurality of gate electrode layers stacked on top of each other on the substrate; a channel region on the cell region of the substrate, the channel region extending through the gate electrode layers in a direction perpendicular to an upper surface of the substrate; a plurality of cell contacts connected to the plurality of gate electrode layers; an active region on the peripheral circuit region of the substrate; a plurality of planar gate electrode layers on the peripheral circuit region and adjacent to the active region; a cover layer on the active region; and a plurality of peripheral contacts connected to the active region and the plurality of planar gate electrode layers. At least a portion of the plurality of peripheral contacts may be separated from the cover layer above the plurality of planar gate electrode layers.

According to example embodiments of inventive concepts, a memory device may include a substrate; a plurality of gate electrode layers stacked on top of each other on the substrate; a plurality of channel regions on the substrate, the channel regions extending through the plurality of gate electrode layers in a direction perpendicular to an upper surface of the substrate; a plurality of peripheral circuit devices on the substrate, the peripheral circuit devices adjacent to the plurality of gate electrodes layers, the peripheral circuit devices including an active region and a plurality of planar gate electrode layers adjacent to the active region; a plurality of cell contacts connected to the plurality of gate electrode layers; a plurality of peripheral contacts connected to the plurality of peripheral circuit devices; and an interlayer insulating layer on the substrate, the interlayer insulating layer including openings that the plurality of cell contacts and the plurality of peripheral contacts extend through.

According to example embodiments of inventive concepts, a method of manufacturing a memory device may include forming a plurality of peripheral circuit devices on a first region of a substrate, the plurality of peripheral circuit devices respectively including an active region, a plurality of planar gate electrode layers adjacent to the active region, and a planar gate spacer covering the plurality of planar gate electrode layers; forming a cover layer on the plurality of peripheral circuit devices; forming a sacrificial layer on the cover layer, the sacrificial layer exposing a portion of the cover layer above the plurality of planar gate electrode layers; removing the portion of the cover layer exposed by the sacrificial layer; removing the sacrificial layer; exposing an upper surface of a second region of the substrate by removing a part of the cover layer that is over the second region of the substrate; and forming a plurality of memory cell devices on the second region of the substrate.

According to example embodiments of inventive concepts, a memory device includes a substrate including a cell region and a peripheral circuit region; a memory cell array on the cell region, the memory cell array including a plurality of memory cell strings that each include a plurality of memory cells stacked on top of each other between a ground selection transistor and a string selection transistor; a plurality of cell contacts connected to the memory cell strings; an active region in the peripheral circuit region; at least one planar transistor on the peripheral circuit region, each planar transistor including a gate electrode on a gate insulating layer that is adjacent to the active region; a spacer covering sidewalls of the gate electrode and gate insulating layer of the at least one planar transistor; a cover layer on the peripheral circuit region, the cover layer covering the active region, the cover layer including an open region that exposes a top surface of the gate electrode of the at least one planar transistor; an interlayer insulating layer on the memory cell array and the cover layer; and a plurality of peripheral contacts connected to the active region and the gate electrode of the least one planar transistor, the plurality of peripheral contacts extending through the interlayer insulating layer.

### BRIEF DESCRIPTION OF DRAWINGS

The foregoing and other features of inventive concepts will be apparent from the more particular description of non-limiting embodiments of inventive concepts, as illustrated in the accompanying drawings in which like reference characters refer to like parts throughout the different views. The drawings are not necessarily to scale, emphasis instead being placed upon illustrating principles of inventive concepts. In the drawings:

FIG. 1 is a schematic block diagram of a memory device according to example embodiments of inventive concepts;

FIG. 2 is a circuit diagram of a memory cell array of a memory device according to example embodiments of inventive concepts;

FIG. 3A is a plan view of a memory device according to example embodiments of inventive concepts;

FIG. 3B is a perspective view of region A of the memory device illustrated in FIG. 3A;

FIGS. 4A through 4D are enlarged views illustrating a portion of a peripheral circuit region of the memory device illustrated in FIG. 3B;

FIGS. 5A, 5B, and 6 are perspective views of a memory device according to example embodiments of inventive concepts;

FIGS. 7 through 22 are drawings illustrating a method of manufacturing a memory device illustrated in FIGS. 3A and 3B;

FIGS. 23 through 27 are drawings illustrating a method of manufacturing a memory device illustrated in FIG. 5A; and

FIGS. 28 and 29 are block diagrams of memory devices according to example embodiments of inventive concepts.

### DETAILED DESCRIPTION

Various example embodiments will now be described more fully with reference to the accompanying drawings in which some embodiments are shown. Example embodiments of inventive concepts may, however, be embodied in different forms and should not be construed as limited to the embodiments set forth herein. Rather, these example embodiments are provided so that this disclosure is thorough and complete and fully conveys the scope of inventive concepts to those skilled in the art. In the drawings, the sizes and relative sizes of layers and regions may be exaggerated for clarity.

Throughout the specification, it will be understood that when an element, such as a layer, region or wafer (substrate), is referred to as being “on,” “connected to,” or “coupled to” another element, it can be directly “on,” “connected to,” or “coupled to” the other element or other elements intervening therebetween may be present. In contrast, when an element is referred to as being “directly on,” “directly connected to,” or “directly coupled to” another element, there may be no elements or layers intervening therebetween. Other words should be interpreted in a similar fashion (e.g., connected versus directly connected). Like numerals refer to like elements throughout. As used herein, the term “and/or” includes any and all combinations of one or more of the associated listed items.

It will be apparent that though the terms first, second, third, etc. may be used herein to describe various members, components, regions, layers and/or sections, these members, components, regions, layers and/or sections should not be limited by these terms. These terms are only used to distinguish one member, component, region, layer or section from another region, layer or section. Thus, a first member, component, region, layer or section discussed below could be termed a second member, component, region, layer or section without departing from the teachings of example embodiments.

Spatially relative terms, such as “above,” “upper,” “below,” and “lower” and the like, may be used herein for ease of description to describe one element's relationship to another element (s) as shown in the figures. It will be understood that the spatially relative terms are intended to encompass different orientations of the device in use or operation in addition to the orientation depicted in the figures. For example, if the device in the figures is turned over, elements described as “above,” or “upper” other elements would then be oriented “below,” or “lower” the other elements or features. Thus, the term “above” can encompass both the above and below orientations depending on a particular direction of the figures. The device may be otherwise oriented (rotated 90 degrees or at other orientations) and the spatially relative descriptors used herein may be interpreted accordingly.

The terminology used herein is for describing particular embodiments only and is not intended to be limiting of inventive concepts. As used herein, the singular forms “a,” “an,” and “the” are intended to include the plural forms as well, unless the context clearly indicates otherwise. It will be further understood that the terms “comprises,” and/or “comprising” when used in this specification, specify the presence of stated features, integers, steps, operations, members, elements, and/or groups thereof, but do not preclude the presence or addition of one or more other features, integers, steps, operations, members, elements, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an etched region or an implanted region illustrated as a rectangle may have rounded or curved features. Thus, the regions illustrated in the figures are schematic in nature and their shapes are not intended to illustrate the actual shape of a region of a device and are not intended to limit the scope of example embodiments.

In example embodiments, a nonvolatile memory may be embodied to include a three dimensional (3D) memory array. The 3D memory array may be monolithically formed on a substrate (e.g., semiconductor substrate such as silicon, or semiconductor-on-insulator substrate). The 3D memory array may include two or more physical levels of memory cells having an active area disposed above the substrate and circuitry associated with the operation of those memory cells, whether such associated circuitry is above or within such substrate. The layers of each level of the array may be directly deposited on the layers of each underlying level of the array.

In example embodiments, the 3D memory array may include vertical NAND strings that are vertically oriented such that at least one memory cell is located over another memory cell. The at least one memory cell may comprise a charge trap layer.

The following patent documents, which are hereby incorporated by reference in their entirety, describe suitable configurations for three-dimensional memory arrays, in which the three-dimensional memory array is configured as a plurality of levels, with word lines and/or bit lines shared between levels: U.S. Pat. Nos. 7,679,133; 8,553,466; 8,654,587; 8,559,235; and US Pat. Pub. No. 2011/0233648.

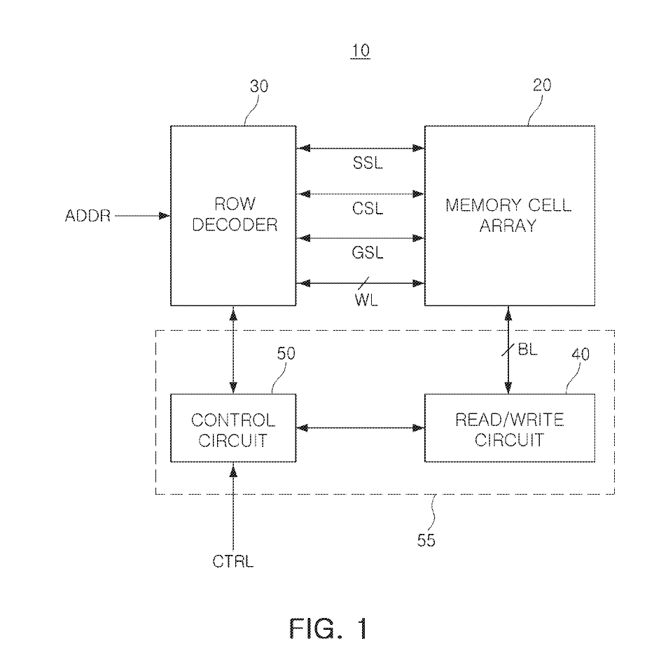

FIG. 1 is a schematic block diagram of a memory device according to example embodiments of inventive concepts.

With reference to FIG. 1, a semiconductor device 10 according to example embodiments of inventive concepts may include a memory cell array 20, a row decoder 30, and a core logic circuit 55. The core logic circuit 55 may include a read/write circuit 40 and a control circuit 50.

The memory cell array 20 may include a plurality of memory cells arranged in a plurality of rows and a plurality of columns. The plurality of memory cells included in the memory cell array 20 may be connected to the row decoder 30 through a word line WL, a common source line CSL, a string select line SSL, a ground select line GSL, and the like, and may be connected to the read/write circuit 40 through a bit line BL. In example embodiments, a plurality of memory cells arranged linearly in a single row may be connected to a single word line WL, and a plurality of memory cells arranged linearly in a single column may be connected to a single bit line BL.

The plurality of memory cells included in the memory cell array 20 may be divided into a plurality of memory blocks. A respective memory block may include a plurality of word lines WL, a plurality of string select lines SSL, a plurality of ground select lines GSL, a plurality of bit lines BL, and at least one common source line CSL.

The row decoder 30 may receive externally provided address information ADDR, and may decode the received address information ADDR to select at least a portion of the word line WL, the common source line CSL, the string select line SSL, and the ground select line GSL connected to the memory cell array 20.

The read/write circuit 40 may select at least a portion of bit lines BL connected to the memory cell array 20 in response to a command provided from the control circuit 50. The read/write circuit 40 may read data written to a memory cell connected to the selected at least a portion of bit lines BL, or may write data to a memory cell connected to the selected at least a portion of bit lines BL. In order to perform operations as described above, the read/write circuit 40 may include a circuit such as a page buffer, an input/output buffer, a data latch, and the like.

The control circuit 50 may control operations of the row decoder 30 and the read/write circuit 40 in response to a control signal CTRL received externally. In the case of reading data written to the memory cell array 20, the control circuit 50 may control operations of the row decoder 30 to supply a voltage to the word line WL in which the data to be read is stored for a read operation. When the voltage for a read operation is supplied to a specific word line WL, the control circuit 50 may perform controlling so that the read/write circuit 40 may read data written to a memory cell connected to the word line WL having received the voltage for a read operation.

In a different manner, for example, when data is written to the memory cell array 20, the control circuit 50 may control operations of the row decoder 30 to supply a voltage for a writing operation to a word line WL to which the data is to be written. When the voltage for a writing operation is supplied to a specific word line WL, the control circuit 50 may control the read/write circuit 40 to write data to a memory cell connected to the word line WL to which the voltage for a writing operation has been supplied.

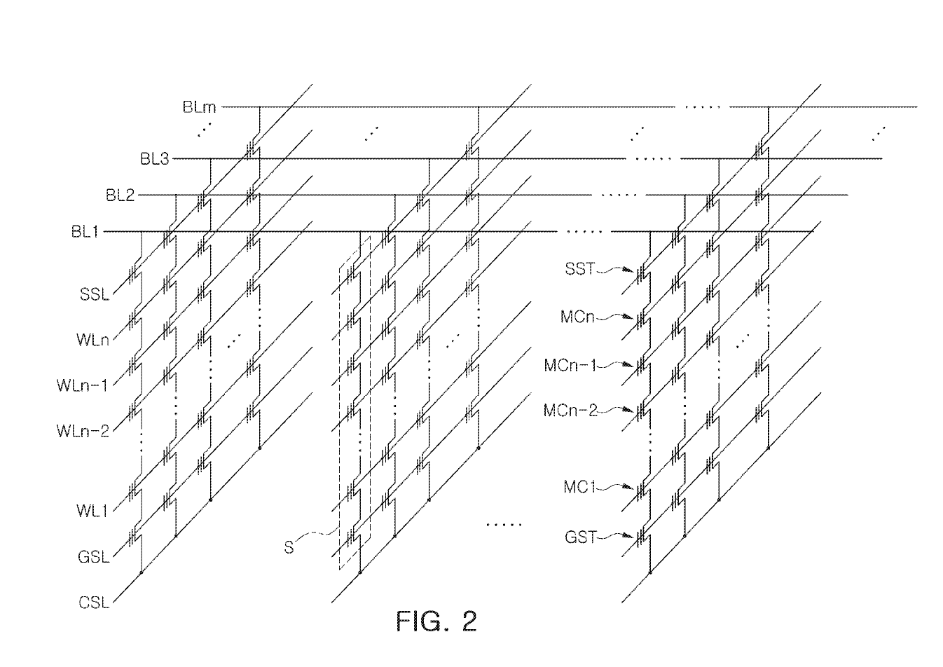

FIG. 2 is an equivalent circuit diagram of a memory cell array of a memory device according to example embodiments of inventive concepts. A semiconductor device according to example embodiments of inventive concepts may be a vertical NAND flash device.

Referring to FIG. 2, a memory cell array may include a plurality of memory cell strings S including n number of memory cells MC1 to MCn connected to one another in series, and a ground selection transistor GST and a string selection transistor SST respectively connected to two ends of the memory cells MC1 to MCn in series. Each of the memory cell strings S may include n memory cells MC1 to MCn stacked on top of each other in a vertical direction between a ground selection transistor and a string selection transistor SST.

The n number of memory cells MC1 to MCn connected to one another in series may be connected to n number of word lines WL1 to WLn to select the memory cells MC1 to MCn, respectively.

Gate terminals of the ground selection transistors GST may be connected to a ground select line GSL, and source terminals thereof may be connected to a common source line CSL. In a different manner, gate terminals of the string selection transistors SST may be connected to a string select line SSL, and source terminals thereof may be connected to drain terminals of memory cells MCn. Although FIG. 2 illustrates a structure in which one ground selection transistor GST and one string selection transistor SST are respectively connected to the n number of memory cells MC1 to MCn connected to one another in series, in a manner different therefrom, a plurality of ground selection transistors GST and/or a plurality of string selection transistors SST may be connected thereto.

Drain terminals of the string selection transistors SST may be connected to a plurality of bit lines BL1 to BLm. When a signal is applied to gate terminals of the string selection transistors SST through the string select line SSL, the signal applied through the bit lines BL1 to BLm may be transferred to the n number of memory cells MC1 to MCn connected to one another in series, and thus a data read operation or a data writing operation may be performed. In addition, as a signal is applied to gate terminals of the ground selection transistors GST of which source terminals are connected to the common source line CSL, via the ground select line GSL, an erase operation in which charges stored in the n number of memory cells MC1 to MCn are overall removed may be performed.

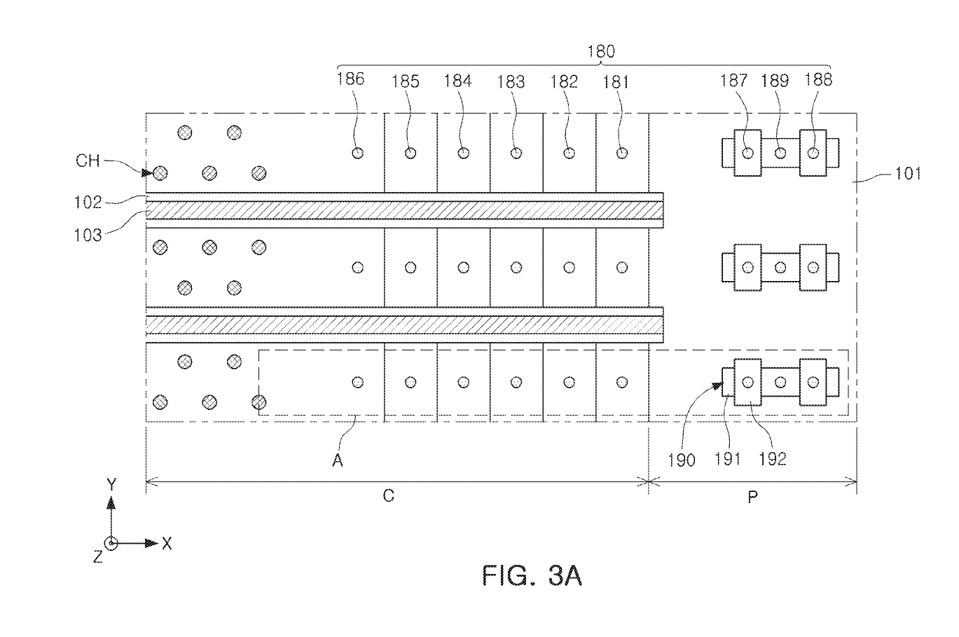

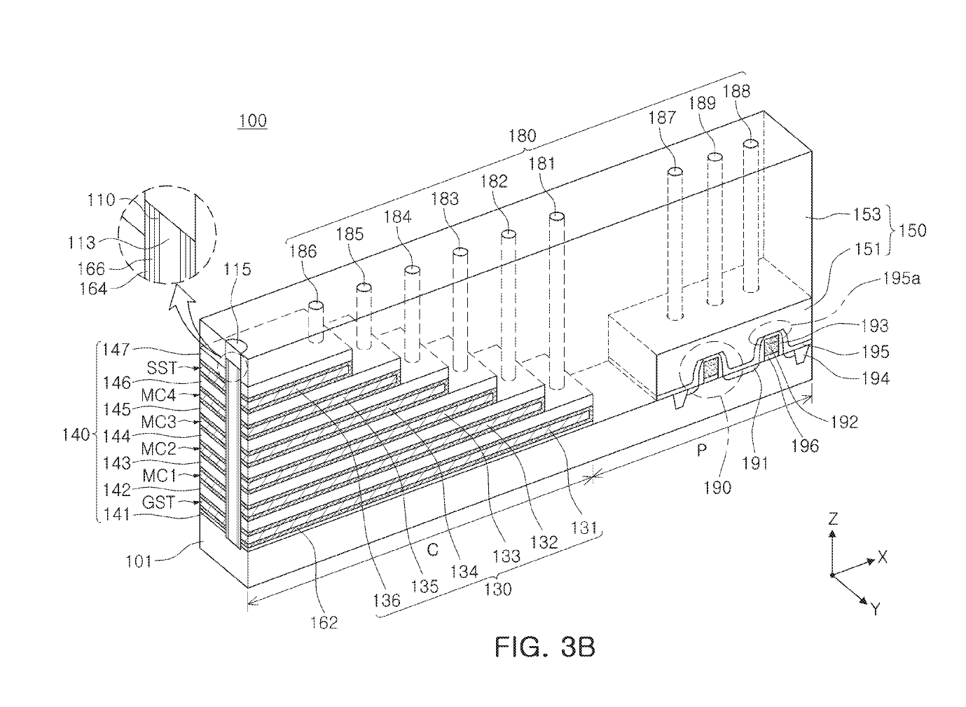

FIG. 3A is a plan view of a memory device according to example embodiments of inventive concepts.

With reference to FIG. 3A, a memory device 100 according to example embodiments of inventive concepts may include a cell region C and a peripheral circuit region P adjacent to the cell region C. The substrate 100 may include the cell region C and the peripheral circuit region P. The cell region C may include channel regions CH extending in a direction perpendicular to an upper surface of a substrate 101, a plurality of cell contacts 181 to 186 connected to a plurality of gate electrode layers stacked on the substrate 101 adjacently to the channel regions CH, and the like. The peripheral circuit region P may include a plurality of peripheral contacts 187 to 189 connected to peripheral circuit devices 190 disposed on the substrate 101. The channel regions CH and the gate electrode layers may be divided into a plurality of regions by isolation insulating layers 102.

An upper surface of the substrate 101 may correspond to an X-Y plane, and the channel regions CH and a plurality of contacts 180 may extend in a direction, for example, a Z-axis direction of FIG. 3A, perpendicular to an upper surface of the substrate 101. The plurality of gate electrode layers connected to the plurality of cell contacts 181 to 186 may be stacked on an upper surface of the substrate 101 parallel to the X-Y plane, in the Z-axis direction.

The channel regions CH may be spaced apart from one another on the X-Y plane. The number and disposition of channel regions CH may be various according to example embodiments. For example, as illustrated in FIG. 3A, the channel regions CH may be disposed in a zig-zag form. In addition, the channel regions CH adjacent to one another with the isolation insulating layer 102 therebetween may be symmetrical to each other, respectively, but are not limited thereto.

The plurality of gate electrode layers and channel regions CH, and the like, may be divided into a plurality of regions by common source lines 103 and the isolation insulating layers 102 disposed in the vicinity of the common source lines 103. The plurality of regions defined by the common source lines 103 and the isolation insulating layers 102 may be respectively provided as a unit cell of the memory device 100. A source region may be disposed below the common source lines 103 in the Z-axis direction.

The peripheral circuit devices 190 may include a planar transistor, and may respectively include an active region 191 provided as a drain region or a source region, or the like, planar gate electrode layers 192, and the like. The active region 191 may be formed by implanting an impurity into a portion of the substrate 101, and the active region 191 and the planar gate electrode layers 192 may intersect each other. The active region 191 and the planar gate electrode layers 192 may be connected to the plurality of peripheral contacts 187 to 189, respectively.

Hereinafter, the memory device 100 according to example embodiments of inventive concepts will be described together with reference to FIG. 3B.

FIG. 3B is a perspective view of region A of the memory device illustrated in FIG. 3A.

With reference to FIG. 3B, the memory device 100 may include a plurality of gate electrode layers 130 (e.g., gate electrode layers 131 to 136) and a plurality of insulating layers 140 (e.g., insulating layers 141 to 147), alternately stacked on an upper surface of the substrate 101 in a Z-axis direction. The plurality of gate electrode layers 130 and the plurality of insulating layers 140 may extend in a single direction, for example, in an X-axis direction of FIG. 3B. The plurality of gate electrode layers 130 and the plurality of insulating layers 140 may be disposed adjacently to a channel region 110 extending in a direction perpendicular to an upper surface of the substrate 101 in the cell region C.

The channel region 110 may extend in the Z-axis direction through holes defined by the insulating layers 140 and the gate electrode layers 130. The channel region 110 may have a circularly shaped cross sectional surface, and may have a hollow circular ring shape. A space formed in a central portion of the channel region 110 may be filled with an embedded insulating layer 113, and a conductive layer 115 may be formed on the channel region 110. The conductive layer 115 may be connected to a bit line to be provided as drain regions of a plurality of memory cell devices disposed in the cell region C.

Respective gate electrode layers 130 may provide gate electrodes of a ground selection transistor GST, a plurality of memory cell transistors MC1 to MCn, and a string selection transistor SST. The gate electrode layers 130 may extend while forming word lines WL1 to WLn, and may be commonly connected to memory cell strings adjacent to each other which are provided by a desired (and/or alternatively predetermined) unit and are arranged in a first direction (X-axis direction) and a second direction (Y-axis direction). In example embodiments, the total number of gate electrode layers 130 configuring the memory cell transistors MC1 to MCn may be 2^{N}, wherein N may be a natural number.

The gate electrode layer 131 of the ground selection transistor GST may be connected to the ground select line GSL. Although FIG. 3B illustrates one gate electrode layer 136 of the string selection transistor SST and one gate electrode layer 131 of the ground selection transistor GST, example embodiments of inventive concepts are not limited thereto. In a different manner, the gate electrode layers 131 and 136 of the ground selection transistor GST and the string selection transistor SST may have a structure different from that of gate electrode layers 132 to 135 of the memory cell transistors MC1 to MCn.

The plurality of gate electrode layers 130 may include polycrystalline silicon or a metal silicide material. The metal silicide material may be a silicide material of a metal selected from among, for example, cobalt (Co), nickel (Ni), hafnium (Hf), platinum (Pt), tungsten (W), and titanium (Ti). According to example embodiments, the plurality of gate electrode layers 130 may also include a metal such as tungsten (W). In addition, although not illustrated in the drawings, the plurality of gate electrode layers 130 may further include a diffusion barrier layer, and for example, the diffusion barrier layer may contain at least one of tungsten nitride (WN), tantalum nitride (TaN), and titanium nitride (TiN).

The plurality of insulating layers 140 stacked alternately with the plurality of gate electrode layers 130 may be separated from each other by the isolation insulating layer 102 in a Y-axis direction in a manner similar to the plurality of gate electrode layers 130. The plurality of insulating layers 140 may include an insulating material such as silicon oxide or silicon nitride.

A gate insulating layer including a blocking layer 162, a charge storage layer 164, a tunneling layer 166, and the like may be disposed between the channel regions 110 and the plurality of gate electrode layers 130. All of the blocking layer 162, the charge storage layer 164, and the tunneling layer 166 may be disposed to encompass the gate electrode layer 130 according to a structure of the memory device 100. Alternatively, a portion of the gate insulating layer may extend in a Z-axis direction to be parallel to the channel region 110 to thus be disposed externally from the channel region 110, and the remaining portion of the gate insulating layer may be disposed to encompass the gate electrode layers 130. In FIG. 3B, the charge storage layer 164 and the tunneling layer 166 may be disposed externally from the channel region 110 to extend in a Z-axis direction so as to be parallel to the channel region 110, and the blocking layer 162 may be disposed to surround the gate electrode layers 130.

The blocking layer 162 may contain silicon oxide (SiO₂), silicon nitride (Si₃N₄), silicon oxynitride (SiON), or a high-k dielectric material. The high-K dielectric material may be any one of Al₂O₃, Ta₂O₃, TiO₂, Y₂O₃, ZrO₂, ZrSiₓO_{y}, HfO₂, HfSiₓO_{y}, La₂O₃, LaAlₓO_{y}, LaHfₓO_{y}, HfAlₓO_{y}, and Pr₂O₃. For example, when the blocking layer 162 contains a high-k dielectric material, the term ‘high-k’ may refer to a dielectric constant of the blocking layer 162 being higher than that of the tunneling layer 166 or higher than a dielectric constant of silicon oxide.

In a different manner, the blocking layer 162 may selectively include a plurality of layers having different dielectric constants. In this case, as a layer having a relatively low dielectric constant is disposed more adjacently to the channel region 110 than a layer having a relatively high dielectric constant thereto, memory device characteristics, such as erase characteristics, may be improved by controlling an energy band having a level equal to a barrier height.

The charge storage layer 164 may be a charge trapping layer or a floating gate conductive layer. For example, when the charge storage layer 164 is a floating gate, the charge storage layer 164 may be formed by depositing poly crystalline silicon using low pressure chemical vapor deposition (LPCVD). For example, when the charge storage layer 164 is a charge trapping layer, the charge storage layer 164 may contain at least one of SiO₂, Si₃N₄, SiON, HfO₂, ZrO₂, Ta₂O₃, TiO₂, HfAlₓO_{y}, HfTaₓO_{y}, HfSi_{X}O_{Y}, AlₓN_{y}, and AlGaₓN_{y}.

The tunnel layer 166 may contain at least one of SiO₂, Si₃N₄, SiON, HfO₂, HfSiₓO_{y}, Al₂O₃, and ZrO₂.

The plurality of peripheral circuit devices 190 may be provided in the peripheral circuit region P. The peripheral circuit devices 190 may include an active region 191 formed by implanting an impurity into the substrate 101, a planar gate electrode layer 192 adjacent to the active region 191, a planar gate spacer 193 covering the planar gate electrode layer 192, and the like. The planar gate spacer 193 may be formed by depositing a silicon oxide layer and the like on the planar gate electrode layer 192 through an MTO process and applying an etch-back process thereto. A planar gate insulating layer 196 may be disposed between the planar gate electrode layer 192 and the substrate 101.

The active region 191 may be provided as a source or drain region of the peripheral circuit device 190, and a device isolation film 194 may be disposed externally from the active region 191. At least a portion of the active region 191 may also be shared by two or more peripheral circuit devices 190 adjacent to each other.

A cover layer 195 may be formed on the peripheral circuit devices 190. The cover layer 195 may include a material having a desired (and/or alternatively predetermined) etch selectivity with respect to the planar gate spacer 193. For example, when the planar gate spacer 193 includes a silicon oxide film, the cover layer 195 may include a silicon nitride film. The cover layer 195 may limit (and/or prevent) the active region 191 or the planar gate electrode layer 192 from being excessively recessed in a process of forming the plurality of peripheral contacts 187 to 189. In a different manner, a portion of the cover layer 195 may be removed from an upper portion of the planar gate electrode layer 192 to thus allow the planar gate spacer 193 to be exposed.

The plurality of gate electrode layers 130 and insulating layers 140 may respectively extend by different lengths in an X-axis direction to form a plurality of step portions with other gate electrode layers 130 and insulating layers 140 stacked on different positions in a Z-axis direction. As the plurality of gate electrode layers 130 and insulating layers 140 extend by different lengths in the X-axis direction to have step portions, respectively, a plurality of pad regions may be provided. Although FIG. 3B illustrates that the insulating layer 140 is located on a position higher than that of the gate electrode layer 130 in the Z-axis direction in the respective pad region, in a manner different therefrom, the gate electrode layer 130 may be located to be higher than the insulating layer 140.

In a different manner, the memory device 100 according to example embodiments of inventive concepts may include an interlayer insulating layer 150 disposed on the substrate 101 in the cell region C and the peripheral circuit region P. The interlayer insulating layer 150 may include a first interlayer insulating layer 151 and a second interlayer insulating layer 153. The first and second interlayer insulating layers 151 and 153 may include the same material, such as silicon oxide. The first interlayer insulating layer 151 may only be disposed in the peripheral circuit region P to cover the peripheral circuit devices 190. In detail, the first interlayer insulation layer 151 may only be disposed in a region in which the peripheral circuit devices 190 are provided. The first interlayer insulating layer 151 may include a high density plasma (HDP) oxide layer filling a space between the plurality of peripheral circuit devices 190 and an upper surface of the substrate 101, and having excellent gap filling characteristics.

The second interlayer insulating layer 153 may be disposed on the substrate 101 in the cell region C and the peripheral circuit region P. The second interlayer insulating layer 153 may be disposed on the pad regions formed by the plurality of gate electrode layers 130 and insulating layers 140 respectively extended by different lengths in a single direction, for example, an X-axis direction of FIG. 3B, in the cell region C, and may be disposed on the first interlayer insulating layer 151 in the peripheral circuit region P.

The second interlayer insulating layer 153 may be formed using a process such as physical vapor deposition (PVD), chemical vapor deposition (CVD), sub-atmospheric chemical vapor deposition (SACVD), low pressure chemical vapor deposition (LPCVD), plasma enhanced chemical vapor deposition (PECVD), or the like. In example embodiments, the second interlayer insulating layer 153 may include a tetra-ethyl-ortho-silicate (TEOS) oxide layer of which a deposition speed is relatively fast.

The plurality of gate electrode layers 130 may be connected to the plurality of cell contacts 181 to 186, respectively, in the pad region, and the planar gate electrode layers 192 and the active region 191 included in the plurality of respective peripheral circuit devices 190 may be connected to the plurality of peripheral contacts 187 to 189. The plurality of contacts 181 to 189 (contacts 180) including the cell contacts 181 to 186 and the peripheral contacts 187 to 189 may penetrate through the interlayer insulating layer 150. The cell contacts 181 to 186 may penetrate through portions of the plurality of interlayer insulating layers 150 and the plurality of insulating layers 140 to be connected to the gate electrode layer 130. The peripheral contacts 187 to 189 may penetrate through the interlayer insulating layer 150, the planar gate spacer 193, and the like to be connected to the planar gate electrode layers 192 or the active region 191.

In order to form a plurality of contacts 180, a mask layer for selective exposure of only a region on which the plurality of contacts 180 are to be formed may be disposed on an upper surface of the second interlayer insulating layer 153, and a plurality of vertical openings may be formed by selectively etching the exposed region exposed through the mask layer. In this case, the vertical openings for the formation of the plurality of cell contacts 181 to 186 may penetrate through a plurality of insulating layers 140 to allow the plurality of gate electrode layers 130 to be exposed in the pad region. A material included in the plurality of gate electrode layers 130 may have a relatively high etch selectivity with respect to the interlayer insulating layer 150 and the insulating layer 140, and after the plurality of gate electrode layers 130 are exposed, since a speed of an etching process is significantly lowered, the plurality of gate electrode layers 130 may not be penetrated.

In a different manner, the vertical openings for the formation of the plurality of peripheral contacts 187 to 189 may penetrate through the cover layer 195 to allow the active region 191 and the planar gate electrode layers 192 to be exposed. As described above, the cover layer 195 may be formed of a material having a desired (and/or alternatively predetermined) etch selectivity with respect to the interlayer insulating layer 150 to limit (and/or prevent) an excessive degree of recess of the active region 191. In addition, the cover layer 195 may not be present on the planar gate electrode layers 192 in such a manner that the planar gate electrode layers 192 may be easily exposed by the vertical openings.

For example, in a comparative example in which the cover layer 195 is present on the entirety of the active region 191 and the planar gate electrode layers 192, when vertical openings for formation of the peripheral contacts 187 to 189 are formed, a relatively long period of process time may be required to allow the planar gate electrode layers 192 to be exposed in the comparative example. Thus, in a case in which the vertical openings for the formation of the cell contacts 181 to 186 and the peripheral contacts 187 to 189 are formed in a single process, a sufficient process time is not able to be secured and thus the planar gate electrode layers 192 may not be exposed. In this case, a defect such as a gate opening in which the peripheral contacts 187 and 189 are not connected to the planar gate electrode layers may occur.

In order to reduce and/or prevent the opening defect that occurs in the comparative example, the cover layer 195 may be removed from upper portions of the planar gate electrode layers 192 according to example embodiments of inventive concepts. In detail, the cover layer 195 may have an open region 195a allowing a planar gate spacer 193 or the planar gate electrode layer 192 to be exposed on an upper portion of the planar gate electrode layer 192. For example, as the open regions 195a are formed on regions in which the planar gate electrode layers 192 are connected to the peripheral contacts 187 and 188, a portion of the planar gate spacers 193 or the planar gate electrode layers 192 may be exposed by the open region 195a.

The peripheral contacts 187 and 188 may be separated from the cover layer 195 on the planar gate electrode layers 192 by the open region 195a. In detail, the peripheral contacts 187 and 188 may be connected to the planar gate electrode layers 192 while not contacting the cover layer 195. In a different manner, on the active region 191 in which the open region 195a is not formed, the peripheral contact 189 may penetrate through the cover layer 195 while contacting the cover layer 195, to thus be connected to the active region 191.

By forming the open region 195a, the configuration of a film material of a region adjacent to the peripheral contacts 187 and 188 connected to the planar gate electrode layers 192 may be simplified. For example, when the interlayer insulating layer 150 and the planar gate spacer 193 contain a silicon oxide, the peripheral contacts 187 and 188 may be formed by only etching the silicon oxide. Since a film material of a region adjacent to the cell contacts 181 to 186 is determined by the second interlayer insulating layer 153 and the insulating layer 140, in a case in which the insulating layer 140 contains a silicon oxide, a film material of the region adjacent to the cell contacts 181 to 186 and a film material of the region adjacent to the peripheral contacts 187 and 188 may be substantially the same as each other. Thus, even when the plurality of cell contacts 181 to 186 and the plurality of peripheral contacts 187 to 189 are formed in a single process, the occurrence of a defect such as a gate opening may be limited (and/or prevented), and thus a process for formation of a plurality of contacts 180 may be reduced, and manufacturing costs may be reduced.

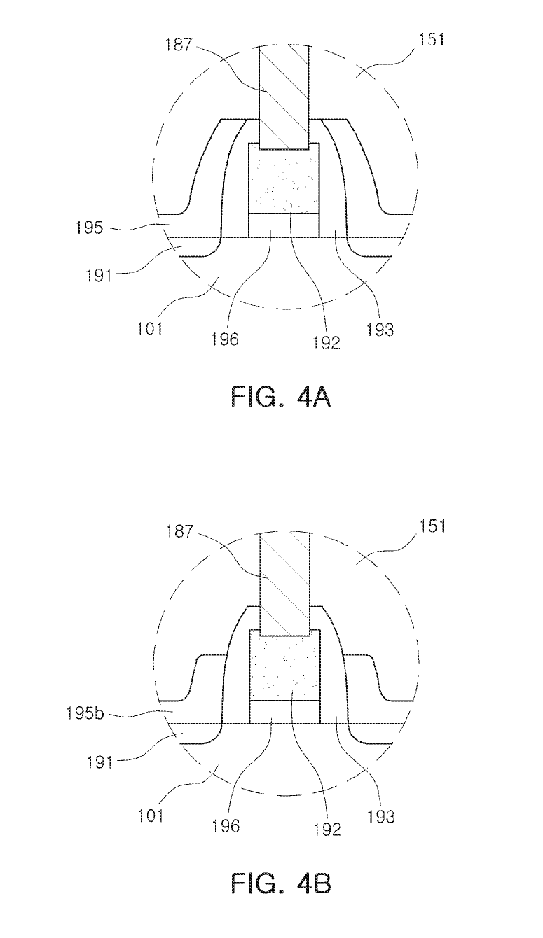

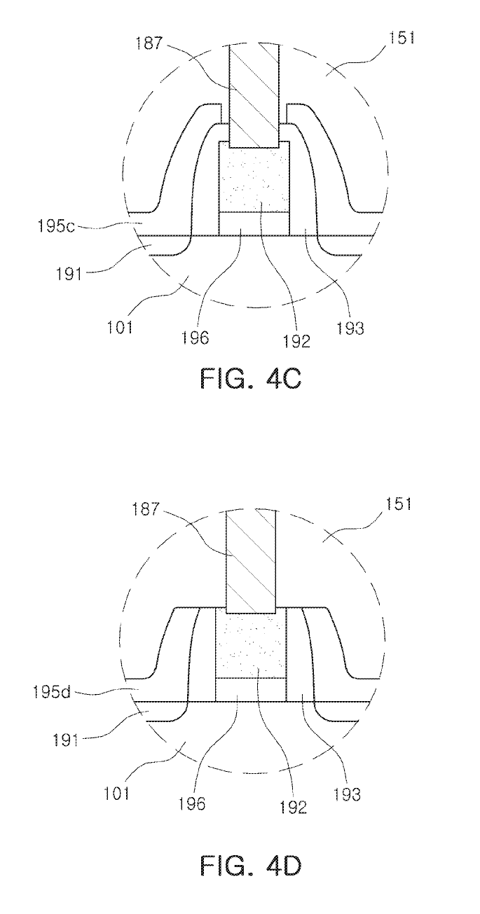

FIGS. 4A through 4D are enlarged views illustrating a portion of a peripheral circuit region of the memory device illustrated in FIG. 3B. FIGS. 4A to 4D may be enlarged views illustrating a portion of a region in which a peripheral circuit device 190 is located in the memory device 100 illustrated in FIG. 3B.

First, with reference to FIG. 4A, the peripheral circuit device 190 may include an active region 191 provided on a substrate 101, a planar gate electrode layer 192 provided on the substrate 101, a planar gate spacer 193 formed on the planar gate electrode layer 192, a planar gate insulating layer 196 disposed between the planar gate electrode layer 192 and the substrate 101, and the like. A cover layer 195 may be formed on the active region 191, and a portion of the cover layer 195 may extend along aside of the planar gate electrode layer 192.

In FIG. 4A, as a portion of the cover layer 192 is removed from an upper portion of the planar gate electrode layer 192, an upper surface of the planar gate spacer 193 may be exposed. The peripheral contact 187 may only penetrate through the interlayer insulating layer 151 and the planar gate spacer 193 to be connected to the planar gate electrode layer 192. Thus, to form a vertical opening for the peripheral contact 187, only the interlayer insulating layer 151 and the planar gate spacer 193 that may be formed of the same material may be removed, thereby reducing a process time. In this case, the vertical opening for the peripheral contact 187 may be formed in the same process as that of the vertical openings for the cell contacts 181 to 186.

Next, with reference to FIG. 4B, a portion of a side of the planar gate spacer 193 may be exposed. For example, a length of a portion of the cover layer 195b extending along a side surface of the planar gate electrode layer 192 may be shorter than that of the cover layer 195b illustrated in FIG. 4A. In addition, in FIG. 4B, the peripheral contact 187 may only penetrate through the interlayer insulating layer 151 and the planar gate spacer 193 to be connected to the planar gate electrode layer 192.

Thus, a process time that a vertical opening for formation of the peripheral contact 187 is formed may be reduced as compared to a case in which the cover layer 195b is present on an upper portion of the planar gate electrode layer 192. As a result, for example, when the peripheral contact 187 is formed in a single process, namely, in the same process as a process in which the cell contacts 181 to 186 are formed, a defect such as a gate opening in which the peripheral contact 187 and the planar gate electrode layer 192 are separated from each other may also be limited (and/or prevented). In a different manner, in FIG. 4B, the cover layer 195b may only be formed on the active region 191, and in this case, a majority of a side surface of the planar gate spacer 193 may be exposed.

In example embodiments of FIG. 4C, a portion of a cover layer 195c may extend to upper portions of the planar gate electrode layer 192 and the planar gate spacer 193. In FIG. 4C, the peripheral contact 187 may also be connected to the planar gate electrode layer 192 in a region from which the cover layer 195c has been removed. In detail, the peripheral contact 187 may penetrate through the cover layer 195c while not contacting the cover layer 195c, to be connected to the planar gate electrode layer 192.

Then, with reference to FIG. 4D, an upper surface of the planar gate electrode layer 192 may be exposed to contact a first interlayer insulating layer 151. The planar gate spacer 193 and the cover layer 195d may be removed from an upper portion of the planar gate electrode layer 192 to allow an upper surface of the planar gate electrode layer 192 to be exposed.

In FIG. 4D, the peripheral contact 187 may only penetrate through the interlayer insulating layer 150 to be connected to the planar gate electrode layer 192. For example, a configuration in which a film material of a layer adjacent to a side surface of the peripheral contact 187 is formed may be substantially the same as a configuration in which a film material of a layer adjacent to side surfaces of the cell contacts 181 to 186 is formed. Thus, in the case that the peripheral contact 187 is formed in a single process, namely, in the same process as a process in which the cell contacts 181 to 186 are formed, a defect such as a gate opening in which the peripheral contact 187 is not connected to the planar gate electrode layer 192 may be limited (and/or prevented).

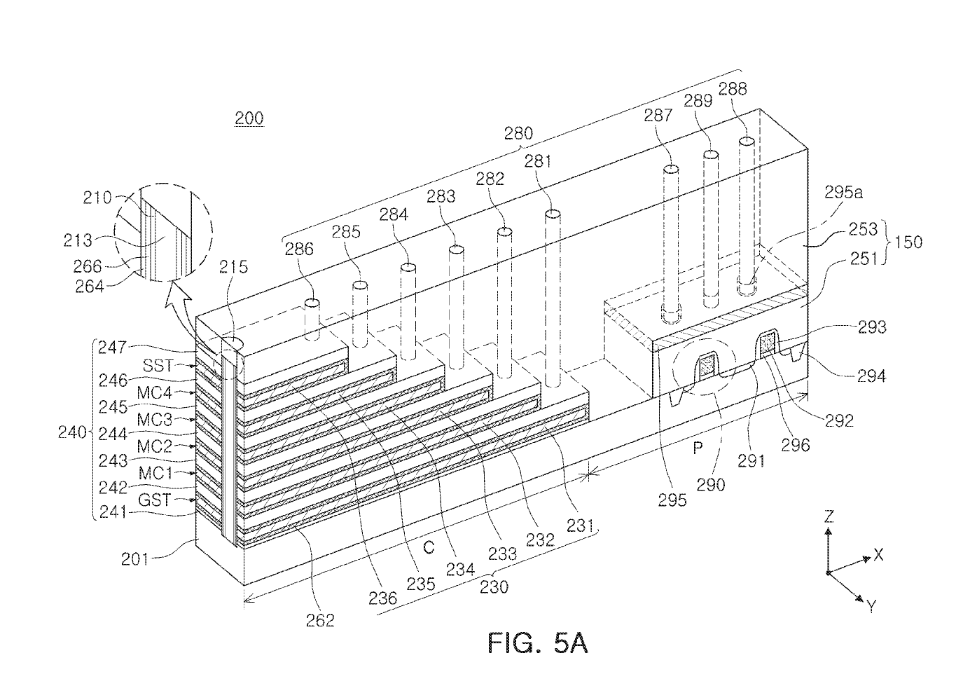

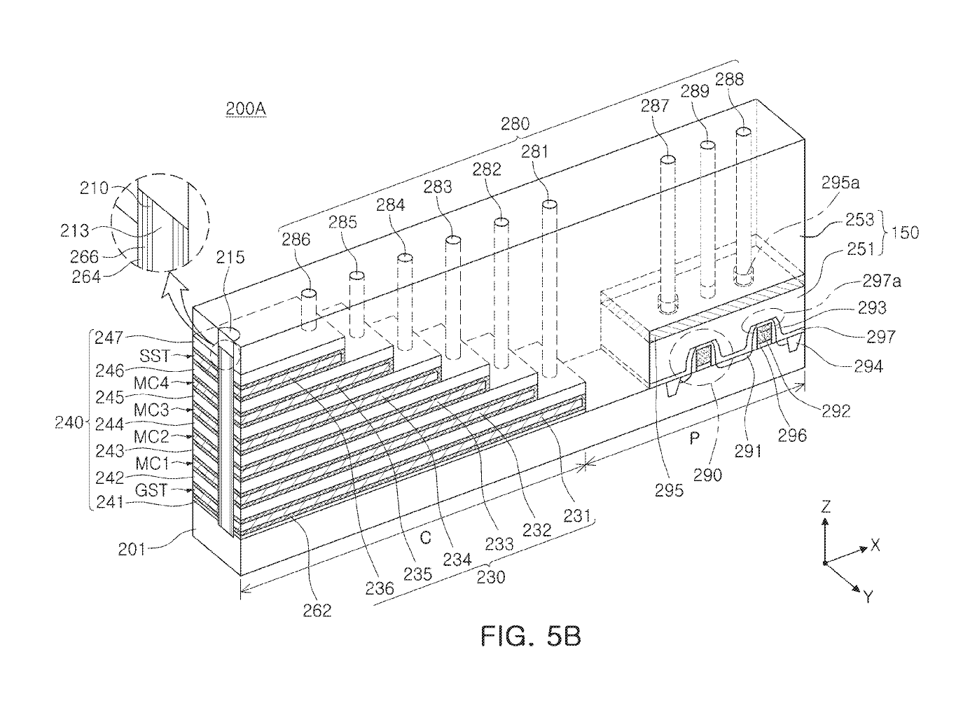

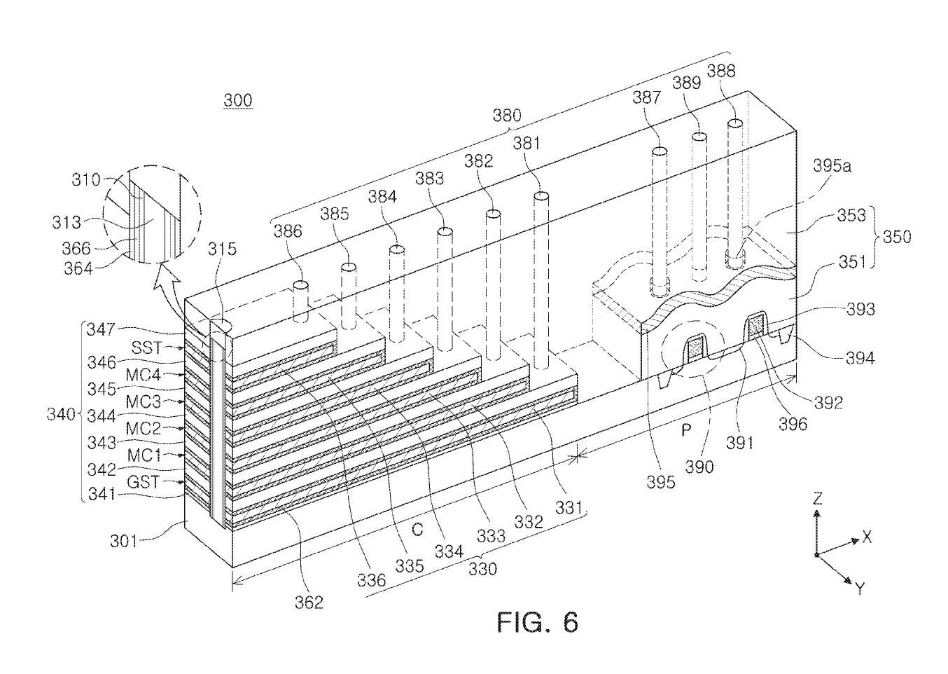

FIGS. 5A, 5B, and 6 are perspective views illustrating portions of a memory device according to example embodiments of inventive concepts.

First, in a manner similar to the memory device 100 with reference to FIGS. 3 and 4, a memory device 200 according to example embodiments illustrated in FIG. 5A may include a channel region 210, memory cells MC1 to MC4, a string selection transistor SST, a ground selection transistor GST, a plurality of gate electrode layers 231 to 236 (gate electrode layers 230), a plurality of cell contacts 281 to 286 connected to the plurality of gate electrode layers 230, respectively, in a cell region C, a peripheral circuit device 290 disposed in a peripheral circuit region P, and a plurality of peripheral contacts 287 to 289 connected to an active region 291 and a planar gate electrode layer 292 of the peripheral circuit device 290, and the like. In FIG. 5A, the cover layer 295 may not be directly formed on an upper surface of the planar gate spacer 293 of the peripheral circuit device 290, but may be disposed on an upper surface of a first interlayer insulating layer 251 covering the peripheral circuit device 290.

The cover layer 295 may include a material having a desired (and/or alternatively predetermined) etch selectivity with respect to a material included in the interlayer insulating layer 250, the planar gate spacer 293, and the like. Thus, for example, when vertical openings for formation of the peripheral contacts 287 to 289 are formed in the same process as a process of the vertical openings for the formation of the cell contacts 281 to 286, the peripheral contacts 287 to 289 may not be connected to the active region 291 or the planar gate electrode layer 292.

In order to limit (and/or prevent) the occurrence of such an opening defect, an open region 295a may be formed in the cover layer 295 according to example embodiments of inventive concepts. In example embodiments, the open region 295a may be formed above the active region 291 or above the planar gate electrode layers 292, connected to the peripheral contacts 287 to 289, and an upper surface of the first interlayer insulating layer 251 may be exposed through the open region 295a. Although FIG. 5A illustrates the case in which open regions 295a are only formed in the cover layer 295 above gate electrode layers 292, the open region 295a may also be formed in an upper portion of the active region 291.

As the open region 295a is formed by removing a portion of the cover layer 295, at least a portion of the peripheral contacts 287 and 288 may pass through the cover layer 295 while not contacting the cover layer 295, to thus be connected to the planar gate electrode layer 292. The peripheral contact 289 formed in a region in which the open region 295a is not formed may penetrate through the cover layer 295 while contacting the cover layer 295, to thus be connected to the active region 291.

Thus, a film material in the vicinity of the peripheral contacts 287 and 288 passing through the open regions 295a may be substantially the same as that in a peripheral region of the cell contacts 281 to 286. In example embodiments, a peripheral region of the peripheral contacts 287 and 288 passing through the open regions 295a and a peripheral region of the cell contacts 281 to 286 may both contain a silicon oxide.

A memory device 200A according to example embodiments illustrated in FIG. 5B may include a plurality of cover layers, for example, a first cover layer 295 and a second cover layer 297. The first cover layer 295 may be disposed on an upper surface of the first interlayer insulating layer 251 such as in FIG. 5A, and the second cover layer 297 may be disposed on an upper surface of a substrate 201. In addition, the second cover layer 297 may be removed from a region except for the active region 291, for example, upper portions of the planar gate electrode layers 292 such as in FIG. 3B.

In detail, both of the first and second cover layers 295 and 297 may not be provided above the planar gate electrode layers 292, and only the first and second interlayer insulating layers 251 and 253 having the same film material may be disposed thereon. Thus, for example, when the cell contacts 281 to 286 and the peripheral contacts 287 to 289 are formed in a single process, a defect such as a gate opening in which the planar gate electrode layers 292 and the peripheral contacts 287 and 288 are not connected may be limited (and/or prevented).

Next, with reference to FIG. 6, in a manner similar to the memory device 200 described above with reference to FIG. 5A, a memory device 300 according to example embodiments may include a channel region 310, memory cells MC1 to MC4, a string selection transistor SST, a ground selection transistor GST, a plurality of gate electrode layers 331 to 336 (gate electrode layers 330), a plurality of cell contacts 381 to 386 connected to the plurality of gate electrode layers 330, respectively, in a cell region C, a peripheral circuit device 390 disposed in a peripheral circuit region P, a plurality of peripheral contacts 387 to 389 connected to an active region 391 and the planar gate electrode layer 392 of the peripheral circuit device 390, and the like. On the other hand, in FIG. 6, a first interlayer insulating layer 351 may have a curved upper surface to correspond to a shape of the planar gate electrode layer 392 of the peripheral circuit device 390. In addition, a cover layer 395 formed on an upper surface of the first interlayer insulating layer 351 may also have a curved upper surface.

In a manner similar to FIGS. 3A to 5B, a plurality of gate electrode layers 330 and a plurality of insulating layers 340 stacked in a Z-axis direction in a cell region C may extend in a single direction, for example, an X-axis direction to provide a pad region with reference to FIG. 6. An uppermost gate electrode layer 336 and an uppermost insulating layer 347 disposed in a Z-axis direction may extend by a relatively shortest length in a single direction, and a lowermost gate electrode layer 331 and lowermost insulating layers 341 and 342 located in a Z-axis direction to become closest to an upper surface of a substrate 301 may extend by a relatively longest length in a single direction. The insulating layer 341 having a relatively reduced thickness as compared to other insulating layers 342 to 347 may be additionally provided between the lowermost gate electrode layer 331 in a stacking direction and the substrate 301.

A plurality of peripheral circuit devices 390 may be disposed in a peripheral circuit region P, and the peripheral circuit device 390 may include an active region 391, a planar gate electrode layer 392, a planar gate spacer 393, and the like. The active region 391 may be provided as a source or drain region, and a device isolation film 394 may be disposed externally from the active region 391. The active region 391 and the planar gate electrode layers 392 may be connected to the plurality of peripheral contacts 387 to 389 in the peripheral circuit region P.

The cover layer 395 may be disposed on the first interlayer insulating layer 351, and may include at least one open region 395a. The open region 395a may be a region allowing a portion of an upper surface of the first interlayer insulating layer 351 to be exposed, and may be formed in an upper portion of the planar gate electrode layer 392 or the active region 391. As the first interlayer insulating layer 351 is exposed through the open region 395a, at least a portion of the peripheral contacts 387 and 388 may not contact the cover layer 395, and may penetrate through the cover layer 395 through the open region 395a.

By forming the open region 395a, at least a portion of the peripheral contacts 387 to 389 may only penetrate through the interlayer insulating layer 350 or through the interlayer insulating layer 350 and the planar gate spacer 393 to be connected to the active region 391 or the planar gate electrode layer 392, in a manner similar to the cell contacts 381 to 386. Since the interlayer insulating layer 350 and the planar gate spacer 393 may include the same material, even when vertical openings for the formation of the peripheral contacts 387 to 389 and the cell contacts 381 to 386 are formed in a single process, a defect in which the peripheral contacts 387 to 389 are not connected to the active region 391 or the planar gate electrode layer 392 may be limited (and/or prevented). Thus, manufacturing costs of the memory device 300 may be reduced by decreasing process steps.

In a different manner, the second interlayer insulating layer 353 may be disposed on the first interlayer insulating layer 351. The second interlayer insulating layer 353 may cover the first interlayer insulating layer 351 and the cover layer 395. As illustrated in FIG. 6, for example, when the first interlayer insulating layer 351 and an upper surface of the cover layer 395 have a curved upper surface corresponding to a shape of the peripheral circuit device 390, a polishing process, for example, a chemical mechanical polishing (CMP) process of planarizing an upper surface of the first interlayer insulating layer 351 may be omitted after the first interlayer insulating layer 351 is formed. Thus, process operations may be reduced as compared to the case of the memory device 200 according to FIG. 5A.

In FIGS. 5 and 6, the first interlayer insulating layers 251 and 351 may include an HDP oxide layer, and the second interlayer insulating layers 253 and 353 may include a TEOS oxide layer. The first interlayer insulating layer 251 or 351 filling a space between the peripheral circuit devices 290 or between the peripheral circuit devices 390 may include an HDP oxide layer having good gap filling characteristics. The second interlayer insulating layers 253 and 353 occupying a relatively large volume as compared to the first interlayer insulating layers 251 and 351 may include a TEOS oxide layer of which a deposition speed is relatively fast, to shorten a process time. In example embodiments, a ratio of a thickness of the first interlayer insulating layer 251 or 351 to the second interlayer insulating layer 253 or 353 may be in a range of 1:10 to 1:20, but may be variously changed depending on conditions such as the number, thicknesses, and the like of stacked gate electrode layers 230 or 330.

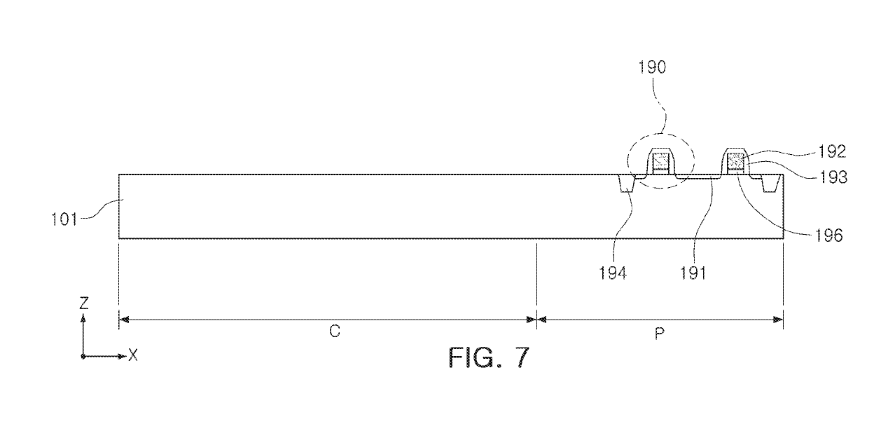

FIGS. 7 through 22 are drawings illustrating a method of manufacturing a memory device illustrated in FIGS. 3A and 3B.

First, referring to FIG. 7, peripheral circuit devices 190 may be formed on a substrate 101 in a method of manufacturing a memory device according to example embodiments of inventive concepts. The peripheral circuit devices 190 may be formed in a peripheral circuit region P provided on a substrate 101. The peripheral circuit region P may be a region adjacent to a cell region C.

The peripheral circuit devices 190 may include a planar transistor, and each of the peripheral circuit devices 190 may include an active region 191, a planar gate electrode layer 192, a planar gate spacer 193, and the like. The active region 191 may be a region formed by implanting an impurity into the substrate 101 by using an ion implantation process or the like, and may be provided as a source or drain region of the peripheral circuit devices 190. The planar gate electrode layer 192 may contain a conductive material such as a metal, polycrystalline silicon, or the like, and a planar gate insulating layer 196 may be disposed between the planar gate electrode layer 192 and the substrate 101.

The planar gate spacer 193 may contain silicon oxide or the like, and may be disposed on the planar gate electrode layer 192. A silicon oxide layer may be formed on the planar gate electrode layer 192 through an MTO process or the like, and the planar gate spacer 193 may be formed by applying an etch back process thereto.

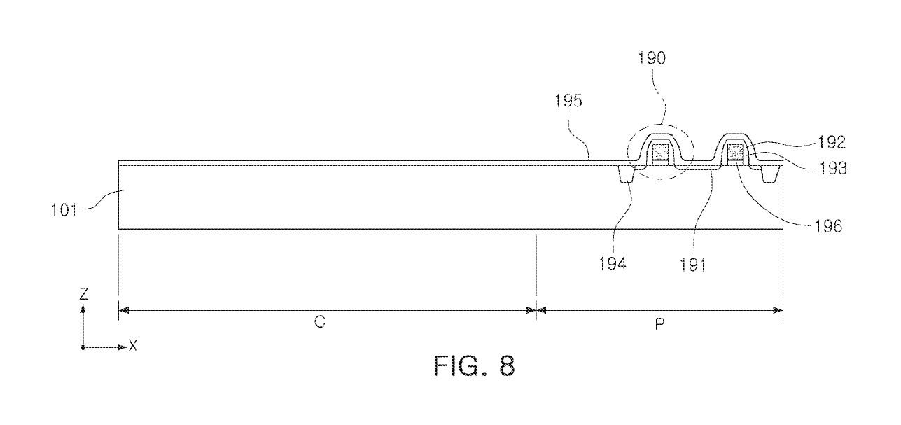

Next, with reference to FIG. 8, the cover layer 195 may be formed on the peripheral circuit devices 190. The cover layer 195 may include a material having a desired (and/or alternatively predetermined) etch selectivity with respect to a material included in the planar gate spacer 193. In example embodiments, for example, when the planar gate spacer 193 contains a silicon oxide, the cover layer 195 may contain a silicon nitride. The cover layer 195 may cover the active region 191, the planar gate spacer 193, and device isolation films 194 included in the peripheral circuit region P.

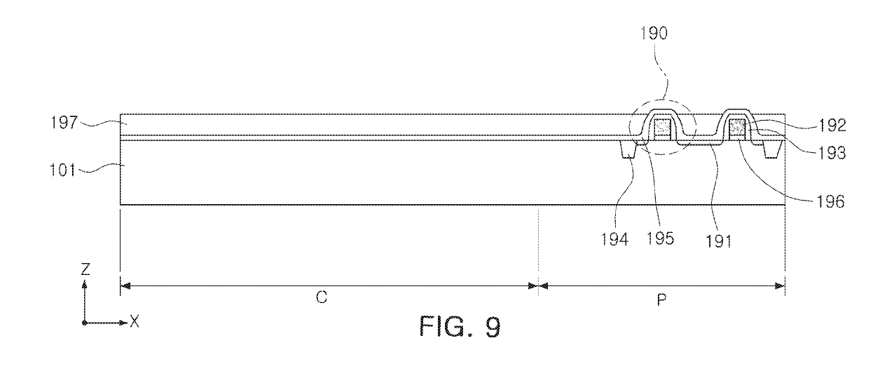

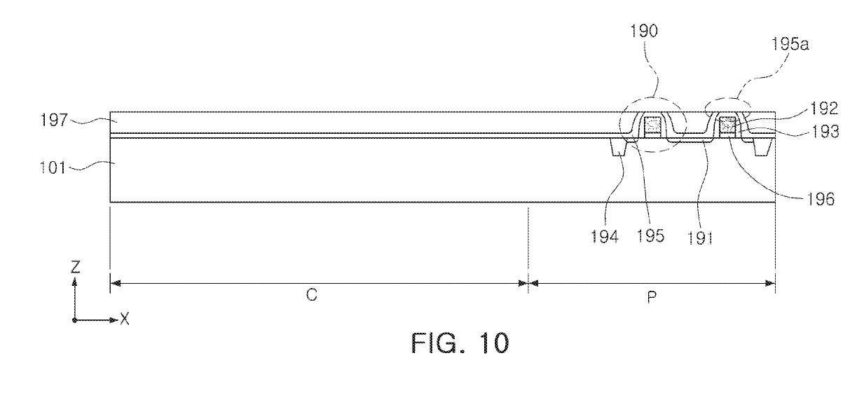

With reference to FIG. 9, a sacrificial layer 197 may be formed on the cover layer 195. The sacrificial layer 197 may be formed to allow a portion of the cover layer 195 to be exposed to an upper portion of the planar gate electrode layer 192. The sacrificial layer 197 may include a material having a desired (and/or alternatively predetermined) etch selectivity with respect to the cover layer 195, and may be provided as a sacrificial layer to enable at least a portion of the cover layer 195 to be removed. In example embodiments, the sacrificial layer 197 may be formed of a material of a spin on hardmask (SOH), such as a hydrocarbon compound containing carbon in a desired (and/or alternatively predetermined) range or a derivative thereof.

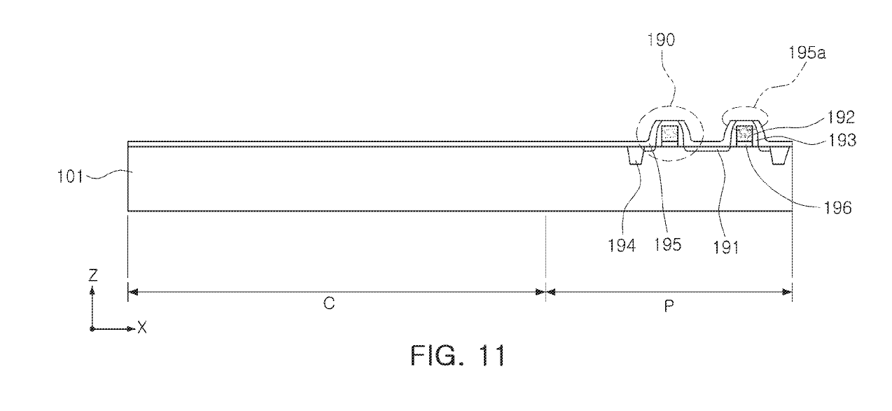

With reference to FIG. 10, the planar gate spacer 193 may be exposed on an upper portion of the planar gate electrode layer 192 by removing a portion of the cover layer 195 exposed by the sacrificial layer 197. A portion of the cover layer 195 may be removed from an open region located above the planar gate electrode layer 192, and the planar gate spacer 193 may be exposed. Subsequently, with reference to FIG. 11, the sacrificial layer 197 may be removed. The sacrificial layer 197 may be removed through an asking and strip process, and may be removed without an additional etching process. An upper surface of the cover layer 195 may be re-exposed on a portion of an upper surface of the substrate 101 by removing the sacrificial layer 197.

In a different manner, although FIG. 11 illustrates that the cover layer 195 has a shape according to FIG. 4A, in a manner different therefrom, a portion of the cover layer 195 may also be removed to have a shape according to FIGS. 4B to 4D. For example, when a portion of the cover layer 195 is removed to have a shape according to FIGS. 4B to 4D, a process in which a mask layer is formed on the cover layer 195 and a portion of the cover layer 195 is exposed to be selectively removed may be used, rather than using a process using a sacrificial layer including SOH.

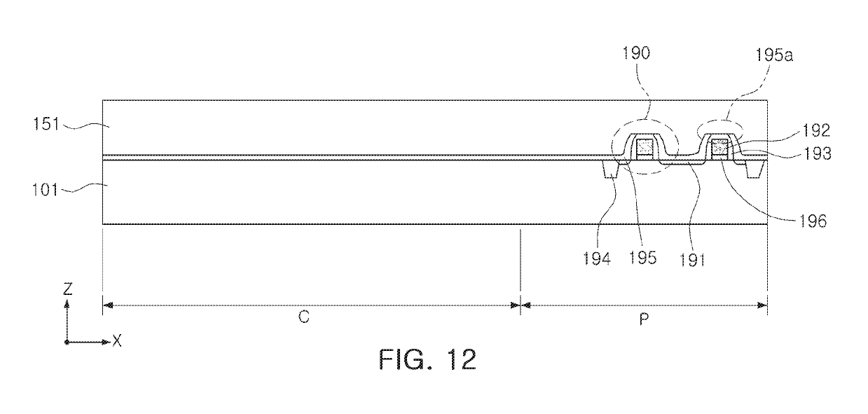

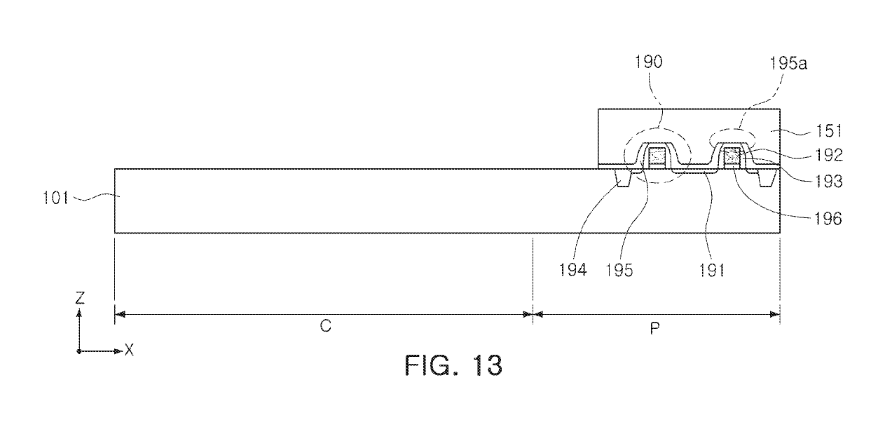

Next, with reference to FIG. 12, a first interlayer insulating layer 151 may be formed on the cover layer 195. The first interlayer insulating layer 151 may include silicon oxide, and may include an HDP oxide layer to easily fill a space between a plurality of planar gate electrode layers 192 and an upper surface of the substrate 101. Subsequently, as illustrated in FIG. 13, a portion of an upper surface of the substrate 101 may be exposed by partially removing the first interlayer insulating layer 151 and the cover layer 195 together. In detail, an upper surface of the substrate 101 may be exposed in a cell region C.

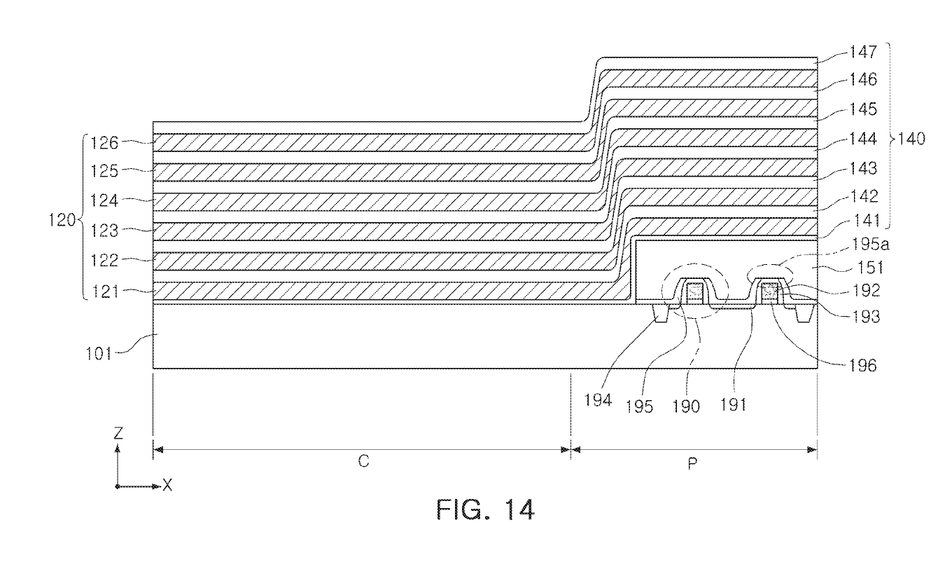

With reference to FIG. 14, a plurality of sacrificial layers 120 (e.g., sacrificial layers 121 to 126) and a plurality of insulating layers 140 (e.g., insulating layers 141 to 147) may be alternately stacked with each other on the substrate 101. The plurality of sacrificial layers 120 may be formed of a material that has a relatively high etch selectivity with respect to the plurality of insulating layers 140 to be able to be selectively etched. Such etch selectivity may be quantitatively represented through a ratio of etching speed of the sacrificial layer 120 to etching speed of the insulating layer 140. For example, the insulating layer 140 may be at least one of a silicon oxide layer and a silicon nitride layer, and the sacrificial layer 120 may be formed of a material layer selected from a silicon layer, a silicon oxide layer, a silicon carbide, and silicon nitride layer, and may include a material different from that of the insulating layer 140. For example, when the insulating layer 140 is a silicon oxide layer, the sacrificial layer 120 may be a silicon nitride layer.

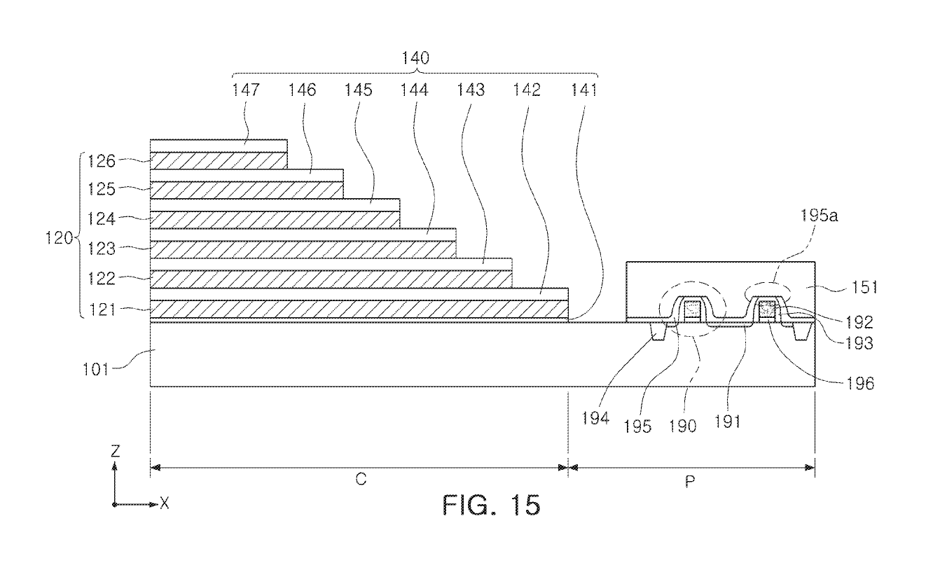

Next, with reference to FIG. 15, the plurality of sacrificial layers 120 and the plurality of insulating layers 140 may be etched to have a stepped structure having step portions.

In order to form the step portions as illustrated in FIG. 15 between the sacrificial layers 120 and the insulating layers 140 adjacent to each other in a Z axis direction, a desired (and/or alternatively predetermined) mask layer may be formed on the plurality of sacrificial layers 130 and insulating layers 140 alternately stacked on the substrate 101, and the sacrificial layers 130 and the insulating layers 140 exposed by the mask layer may be etched. By performing a process of etching the sacrificial layers 120 and the insulating layers 140 exposed by the mask layer while trimming the mask layer a plurality of times, the sacrificial layers 120 and the insulating layers 140 are sequentially etched to have a stepped structure having step portions.

In example embodiments, an insulating layer 140 and a sacrificial layer 120 may be provided as a pair, and a respective pair of the insulating layer 140 and the sacrificial layer 120 included in a plurality of pairs may extend to have the same length in a single direction, for example, in an X-axis direction of FIG. 15. For example, the insulating layers 141 and 142 extending by the same length may be disposed above and below a lowermost sacrificial layer 121 in a Z-axis direction. In this case, the lowermost insulating layer 141 in the Z-axis direction may have a relatively reduced thickness as compared to other insulating layers 142 to 147.

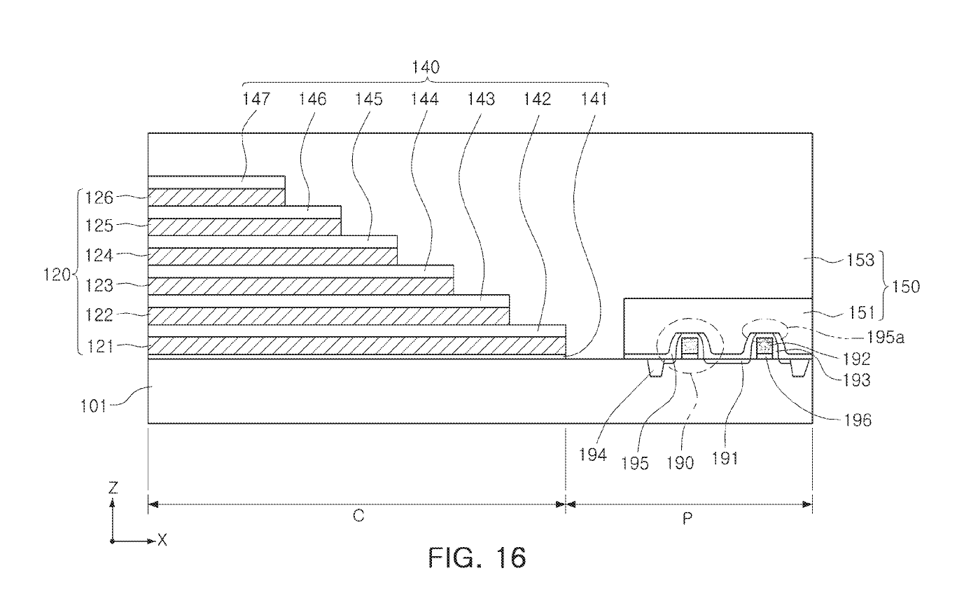

Then, with reference to FIG. 16, the second interlayer insulating layer 153 may be formed on the plurality of sacrificial layers 120 and insulating layers 140. The second interlayer insulating layer 153 may be formed on the substrate 101 in the cell region C and the peripheral circuit region P while being formed on the plurality of sacrificial layers 120 and insulating layers 140 and the first interlayer insulating layer 151. The second interlayer insulating layer 153 may contain silicon oxide similar to the first interlayer insulating layer 151. The second interlayer insulating layer 153 may have a relatively large volume as compared to the first interlayer insulating layer 151, and thus, may include a TEOS oxide layer having a relatively fast deposition speed.

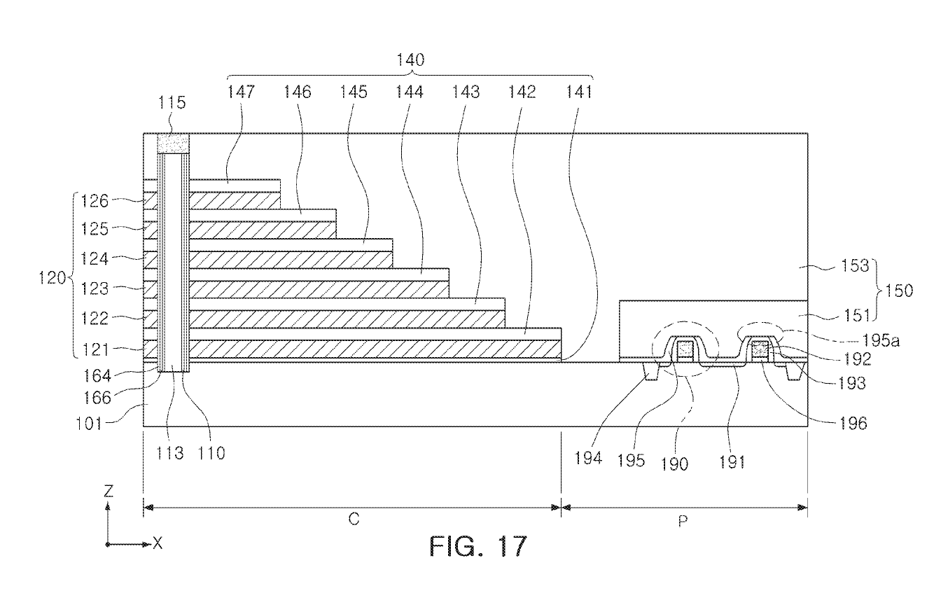

When the interlayer insulating layer 150 is formed, a channel region 110 may be formed as illustrated in FIG. 17. In order to form the channel region 110, a channel opening extending from an upper surface of the second interlayer insulating layer 153 to an upper surface of the substrate 101 may be formed. The channel region 110, an embedded insulating layer 113, a conductive layer 115, and the like may be formed inside the channel opening. The channel region 110 may have a form recessed from an upper surface of the substrate 101 into a portion of the substrate 101. In example embodiments, an epitaxial layer formed by selective epitaxial growth may be further formed between the channel region 110 and the substrate 101.

In a different manner, at least a portion of a gate insulating layer, for example, a charge storage layer 164 and a tunneling layer 166 may be formed externally from the channel region 110. The charge storage layer 164 and the tunneling layer 166 may be formed through a process such as ALD, CVD, or the like, and may be sequentially stacked from a position thereof adjacent to the plurality of sacrificial layers 120 and insulating layers 140. The channel region 110 may be formed to have a desired (and/or alternatively predetermined) thickness in a range of 1/50 to ⅕ of a width of the channel opening, and may be formed through ALD or CVD in a manner similar to the charge storage layer 164 and the tunneling layer 166.

An internal space of the channel region 110 may be filled with the embedded insulating layer 113. Selectively, before the embedded insulating layer 113 is formed, a hydrogen annealing operation in which a structure having the channel region 110 is heat-treated under an atmosphere of gas including hydrogen or heavy hydrogen may be further performed. A majority of crystal defects present in the channel region 110 may be limited (and/or prevented) by the hydrogen annealing operation. Next, the conductive layer 115 may be formed on an upper portion of the channel region 110 using a conductive material such as polycrystalline silicon or the like. The conductive layer 115 may be connected to a bit line to be provided as a drain region of a memory cell device.

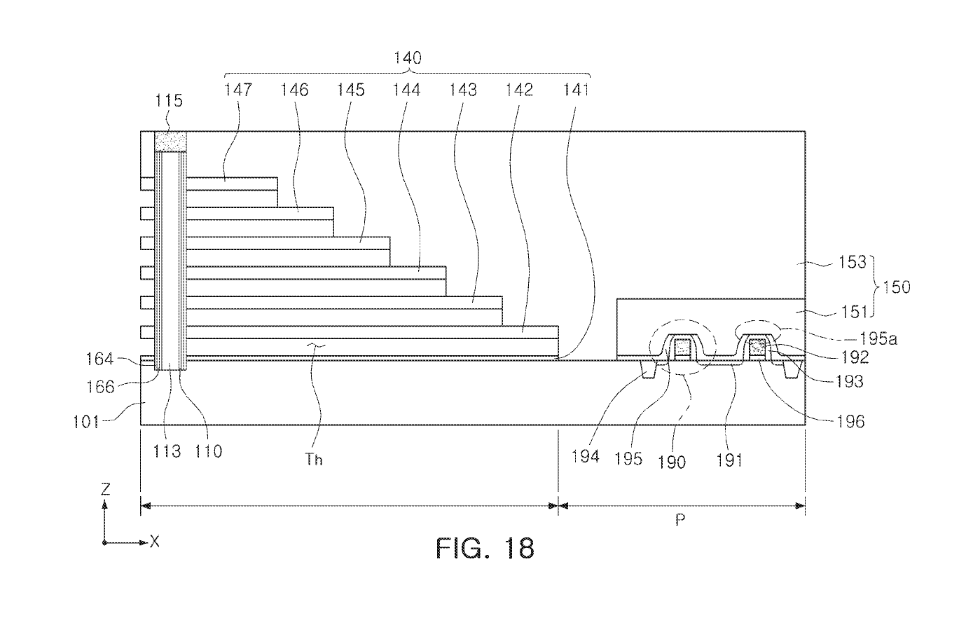

Subsequently, with reference to FIG. 18, a plurality of horizontal openings Th may be formed by removing the sacrificial layers 120. In order to form the isolation insulating layer 102 as illustrated in FIG. 3A, openings partitioning the plurality of sacrificial layers 120 and insulating layers 140 into a plurality of sections may be formed in the cell region C, and the sacrificial layers 120 may be selectively removed through the openings. A conductive material may be deposited in the horizontal openings Th from which the sacrificial layers 120 have been removed to thus form gate electrode layers 131 to 136 (gate electrode layers 130).

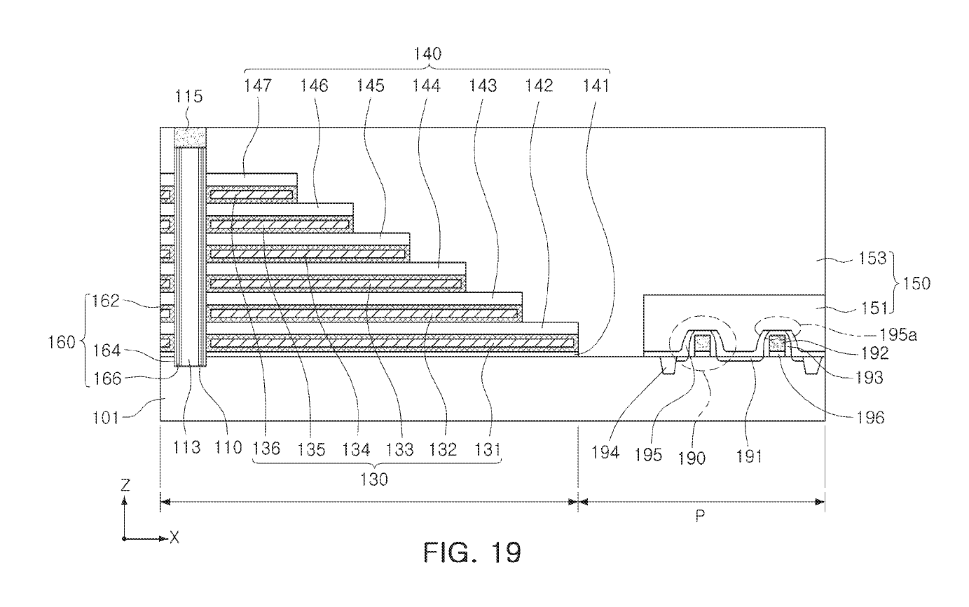

With reference to FIG. 19, the plurality of gate electrode layers 130 may be formed in the horizontal openings Th. In this case, before the gate electrode layer 130 is formed, a blocking layer 162 may be first formed on an inner wall of the horizontal opening Th. The gate electrode layer 130 may contain polycrystalline silicon, or a metal silicide material. The metal silicide material may be a silicide material of a metal selected from among, for example, cobalt (Co), nickel (Ni), hafnium (Hf), platinum (Pt), tungsten (W), and titanium (Ti), or may be a combination thereof. For example, when the gate electrode layer 130 is formed of a metal silicide material, the gate electrode layer 130 may be formed by forming a separate metal layer and performing a silicidation process thereon after side openings are filled with silicon (Si). After the gate electrode layer 130 is formed, an insulating material and a conductive material may be deposited in the openings partitioning the plurality of sacrificial layers 120 and insulating layers 140 into a plurality of sections to thus form an isolation insulating layer 102 and a common source line 103.

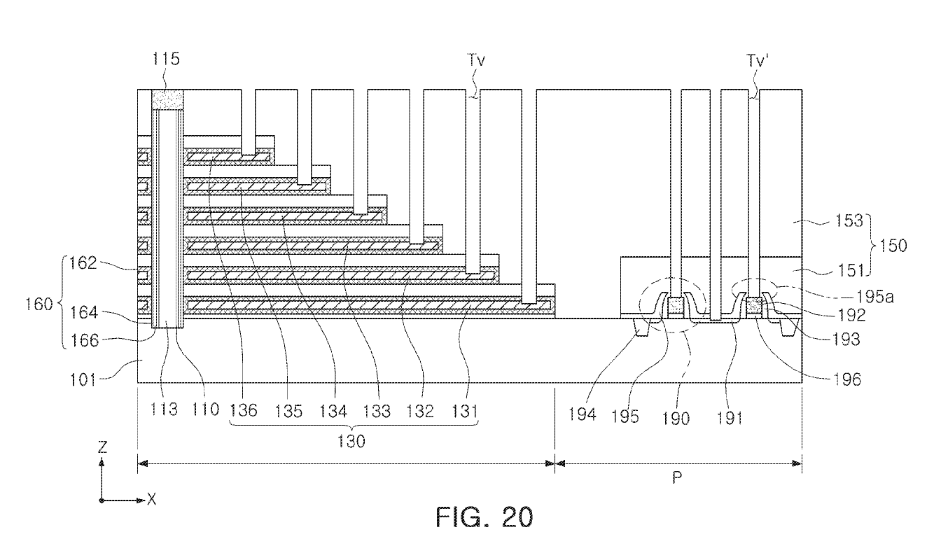

Next, with reference to FIG. 20, contact openings Tv and Tv′ for formation of a plurality of contacts may be formed. The contact openings Tv and Tv′ may include cell contact openings Tv formed in the cell region C and peripheral contact openings Tv′ formed in the peripheral circuit region P. The cell contact openings Tv may be formed to have depths allowing the respective gate electrode layers 130 extending by different lengths in the cell region C to be exposed. The peripheral contact openings Tv′ may be formed to have depths allowing the active region 191 and the planar gate electrode layers 192 to be exposed in the peripheral circuit region P.

In a memory device with a general structure, materials of layers through which the cell contact openings Tv and the peripheral contact openings Tv′ penetrate may be different from each other. The cell contact openings Tv may penetrate through the second interlayer insulating layer 153 and the insulating layers 140 formed of the same material, while layers through which the peripheral contact openings Tv′ penetrate may be the interlayer insulating layer 150, the cover layer 195, and the planar gate spacer 193, and here, the cover layer 195 may contain a material different from a material of the interlayer insulating layer 150 and the planar gate spacer 193.

Thus, for example, when the cell contact openings Tv and the peripheral contact openings Tv′ are formed in a single process, the peripheral contact openings Tv′ may be relatively slowly formed in such a manner that a portion of the active region 191 and the planar gate electrode layers 192 may not be exposed by the peripheral contact openings Tv′. Such an opening defect in which a length of the peripheral contact openings Tv′ is not sufficiently formed may occur above the planar gate electrode layers 192 with a relatively complicated upper film material at a relatively high probability. In order to limit and/or prevent an opening defect, a scheme in which the cell contact openings Tv and the peripheral contact openings Tv′ are formed in separate processes has been proposed. However, in this case, process steps may be increased and process costs may be increased.

In example embodiments, in order to form the contact openings Tv and Tv′ in a single process without increasing process steps and process costs, as described above with reference to FIGS. 9 to 11, a portion of the cover layer 195 may be removed from upper portions of the planar gate electrode layers 192. By providing open regions 195a by removing the cover layer 195 from upper portions of the planar gate electrode layers 192, layers through which the contact openings Tv′ penetrate above the planar gate electrode layers 192 may be defined as the interlayer insulating layer 150 and the planar gate spacer 193. The interlayer insulating layer 150 and the planar gate spacer 193 may include the same material, for example, silicon oxide. Thus, for example, even when the cell contact openings Tv and the peripheral contact openings Tv′ are formed in a single process, the active region 191 and the planar gate electrode layers 192 may be exposed from lower portions of the peripheral contact openings Tv′. In addition, a depth of the peripheral contact opening Tv′ recessed into the active region 191 may be easily controlled. On the other hand, although a portion of the cover layer 195 is described as being only removed from the upper portions of the planar gate electrode layers 192, a portion of the cover layer 195 may also be removed from an upper portion of the active region 191 according to various example embodiments.

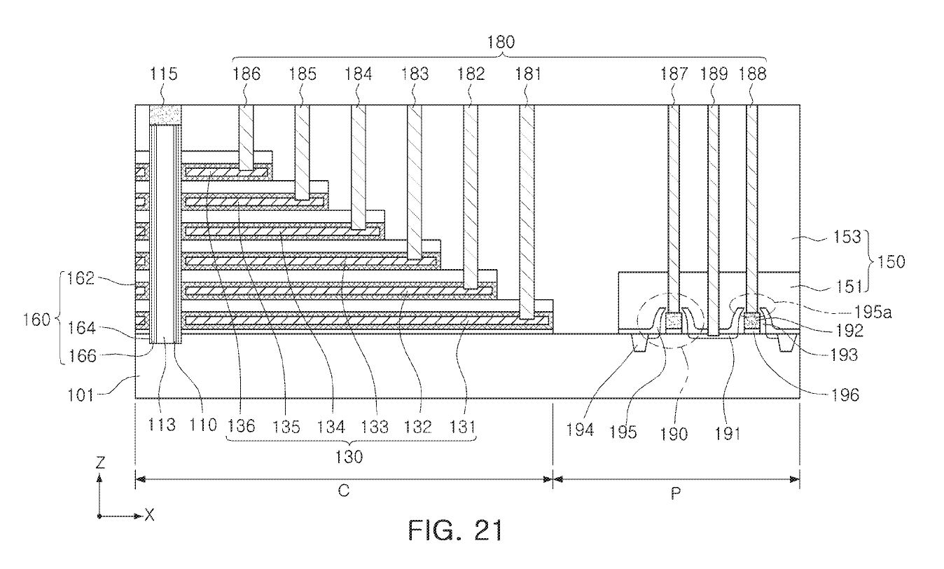

Subsequently, with reference to FIG. 21, a plurality of contacts 181 to 189 (contacts 180) may be formed by filling the plurality of contact openings Tv and Tv′ with a conductive material. The plurality of contacts 180 may include a plurality of cell contacts 181 to 186 connected to the plurality of gate electrode layers 130 in the cell region C, a plurality of peripheral contacts 187 to 189 connected to the active region 191 or the planar gate electrode layers 192 in the peripheral circuit region P, and the like.

A portion of the plurality of peripheral contacts, for example, the peripheral contacts 187 and 188 may penetrate through the interlayer insulating layer 150 and the like without contacting the cover layer 195, to be connected to the active region 191 or the planar gate electrode layers 192, while a portion of the plurality of peripheral contacts, for example, the peripheral contact 189 may penetrate through the cover layer 195 while contacting the cover layer 195 to be connected to the active region 191 or the planar gate electrode layer 192. As described above, in order to form the contact openings Tv and Tv′ for formation of the plurality of contacts 180 in a single process, a portion of the cover layer 195 may be removed from an upper portion of the active region 191 or the planar gate electrode layers 192. By removing a portion of the cover layer 195, a material of a layer above the active region 191 or the planar gate electrode layer 192 may be simplified, and the contact openings Tv and Tv′ may be formed in a single process.

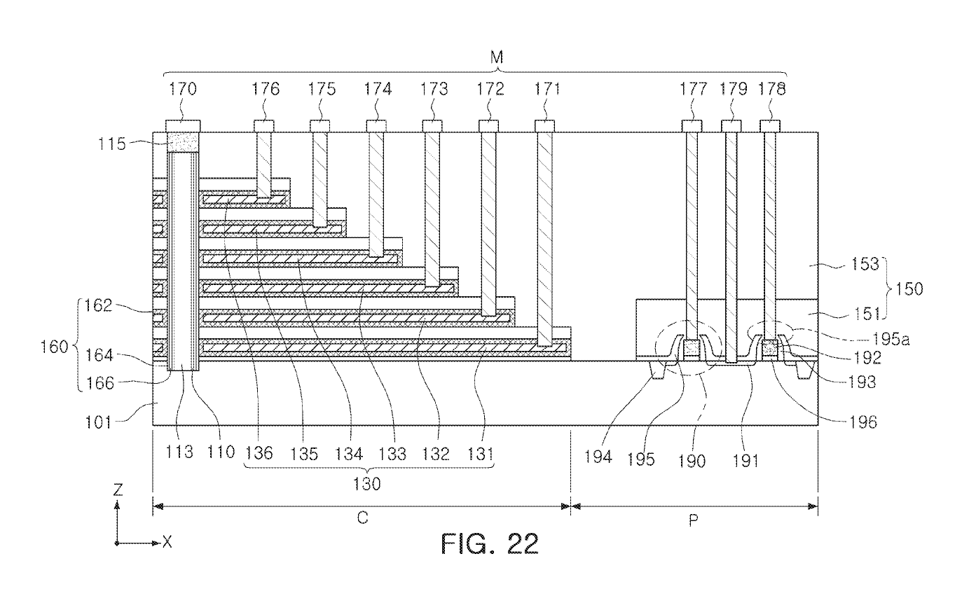

With reference to FIG. 22, a plurality of metal lines 170 to 179 (metal lines M) may be formed on an upper surface of the interlayer insulating layer 150. The metal line 170 disposed on the channel region 110 may be a bit line, and the metal lines 171 to 176 disposed on the cell contacts 181 to 186 may be word lines.

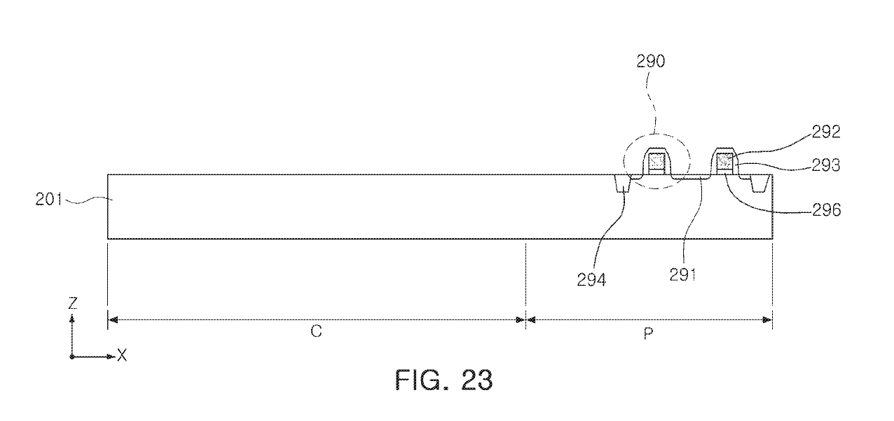

FIGS. 23 through 27 are drawings illustrating a method of manufacturing a memory device illustrated in FIG. 5A.

With reference to FIG. 23, a plurality of peripheral circuit devices 290 may be disposed on a substrate 201 in the peripheral circuit region P. Each of the peripheral circuit devices 290 may include an active region 291, a planar gate electrode layer 292, a planar gate spacer 293, and the like. A device isolation film 294 may be disposed externally from the active region 291, and a planar gate insulating layer 296 may be disposed between the planar gate electrode layer 292 and an upper surface of the substrate 201.

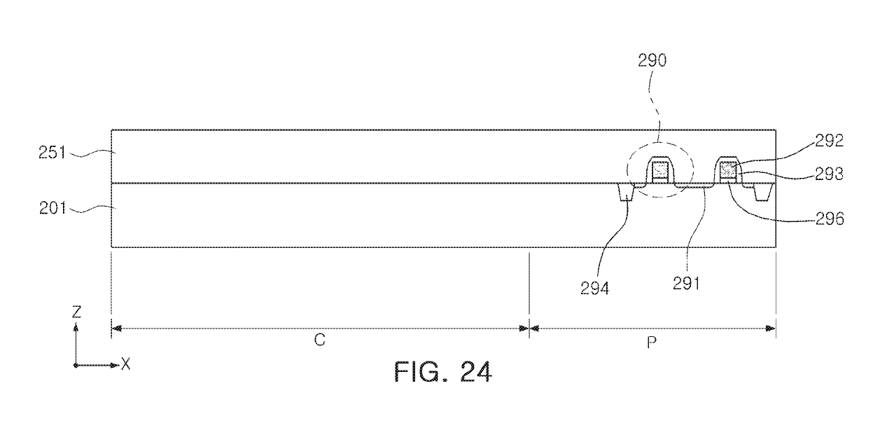

Next, with reference to FIG. 24, a first interlayer insulating layer 251 may be disposed on the peripheral circuit device 290. The first interlayer insulating layer 251 may include an HDP oxide layer having excellent gap filling characteristics to fill a space formed between the peripheral circuit device 290 and an upper surface of the substrate 201, and may be formed of silicon oxide.

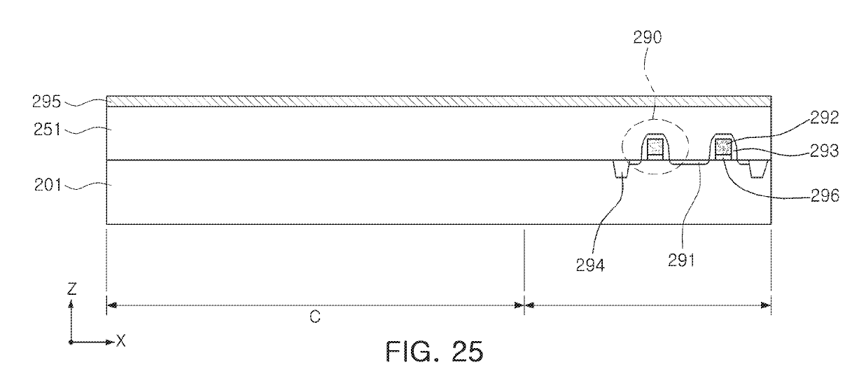

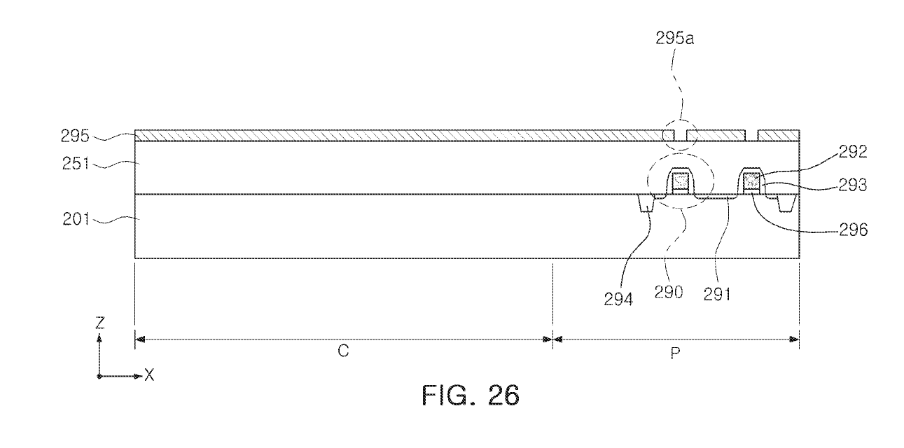

With reference to FIG. 25, the cover layer 295 may be formed on an upper surface of the first interlayer insulating layer 251. The cover layer 295 may include a material having a desired (and/or alternatively predetermined) etch selectivity with respect to the first interlayer insulating layer 251. In example embodiments, for example, when the first interlayer insulating layer 251 is formed of a silicon oxide, the cover layer 295 may contain silicon nitride. Then, with reference to FIG. 26, the open region 295a may be formed by removing a portion of the cover layer 295.

Since a portion of the cover layer 295 is removed to form the open region 295a, an upper surface of the first interlayer insulating layer 251 may be exposed through the open region 295a. The open regions 295a may be formed above the planar gate electrode layers 292 in such a manner that a portion of the peripheral contacts 287 to 289 formed in a subsequent process may penetrate through the open regions 295a to be connected to the planar gate electrode layers 292.

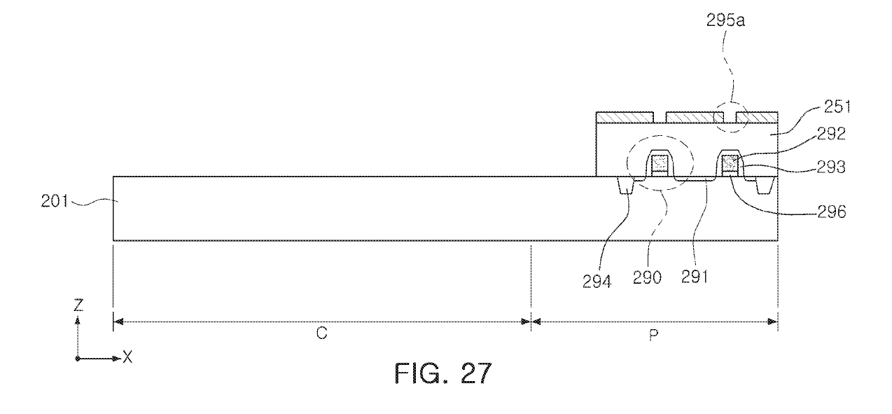

Next, with reference to FIG. 27, an upper surface of the substrate 201 may be exposed by selectively removing portions of the first interlayer insulating layer 251 and the cover layer 295, in the cell region C. In a subsequent process, a plurality of insulating layers 240 and gate electrode layers 230 are alternately stacked on an upper surface of the substrate 201, and a channel region 210 may be formed in a direction perpendicular to an upper surface of the substrate 201. A subsequent process may be similar to the process described above with reference to FIGS. 14 to 22.

In a manner similar to that of FIGS. 14 to 22, a portion of the peripheral contacts 287 to 289, for example, the peripheral contacts 287 and 288 connected to the planar gate electrode layers 292 may only penetrate through the interlayer insulating layer 250 and the planar gate spacer 293 without contacting the cover layer 295. Thus, vertical openings for formation of the peripheral contacts 287 to 289 and the cell contacts 281 to 286 may be formed together in a single process. Thus, process steps and manufacturing costs may be reduced. Further, the cover layer 295 may also have an open region 295a formed in a portion thereof, above the active region 291, according to a process condition, a structure of the memory device 200, and the like.

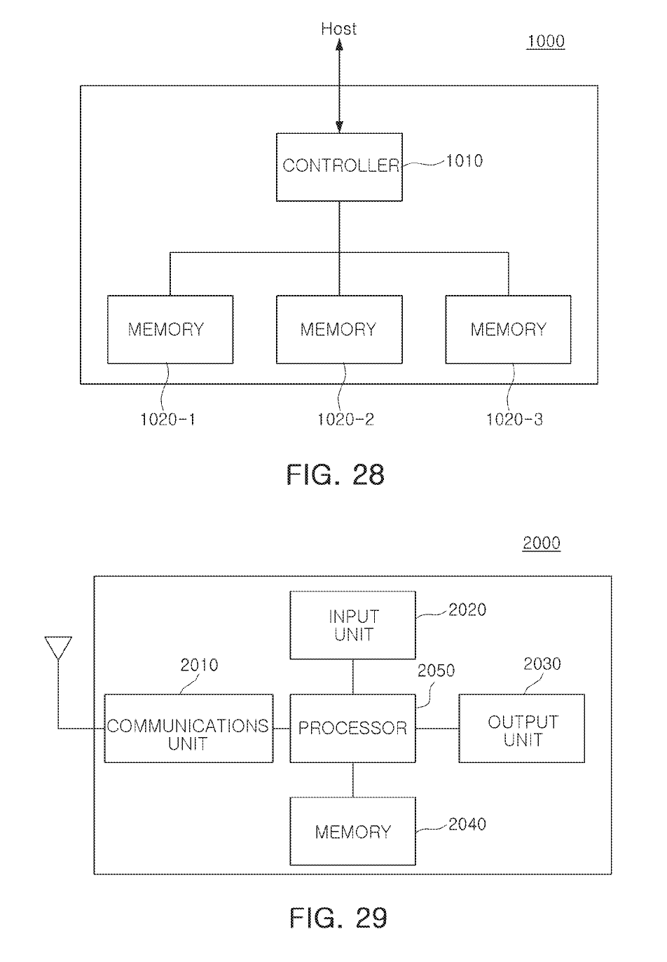

FIGS. 28 and 29 are block diagrams of an electronic device including a memory device according to example embodiments of inventive concepts.

With reference to FIG. 28, a storage device 1000 according to example embodiments may include a controller 1010 communicating with a host and memories 1020-1, 1020-2, and 1020-3 storing data therein. The respective memories 1020-1, 1020-2, and 1020-3 may include at least one of the above-described memory devices 100, 200, or 300 according to example embodiments.

The host communicating with the controller 1010 may be various electronic devices in which the storage device 1000 is installed, and for example, may be a smartphone, a digital camera, a desktop computer, a laptop computer, a portable media player, or the like. The controller 1010 may receive a data writing or data reading request transferred by the host to enable data to be written to the memories 1020-1, 1020-2, and 1020-3, or may generate a command CMD to allow data to be read from the memories 1020-1, 1020-2, and 1020-3.

As illustrated in FIG. 28, one or more memories 1020-1, 1020-2, and 1020-3 may be connected to the controller 1010 in parallel within the storage device 1000. The storage device 1000 having a large capacity as in a solid state drive (SSD) may be implemented by connecting the plurality of memories 1020-1, 1020-2, and 1020-3 to the controller 1010 in parallel.

FIG. 29 is a block diagram of an electronic device including a non-volatile memory device according to example embodiments of inventive concepts.

With reference to FIG. 29, an electronic device 2000 according to example embodiments may include a communications unit 2010, an input unit 2020, an output unit 2030, a memory 2040, and a processor 2050.

The communications unit 2010 may include a wired/wireless communications module and may include a wireless Internet module, a near-field communications module, a global positioning system (GPS) module, a mobile communications module, and the like. The wired/wireless communications module included in the communications unit 2010 may be connected to an external communications network via various communications protocols to transmit or receive data.

The input unit 2020 may be a module provided to control operations of the electronic device 2000 by a user, and may include a mechanical switch, a touchscreen, a sound recognition module, and the like. In addition, the input unit 2020 may also include a mouse operating in a trackball or laser pointer scheme, or the like, or a finger mouse device, and may further include various sensor modules through which data may be input by a user.

The output unit 2030 may output information processed by the electronic device 2000 in audio or visual form, and the memory 2040 may store a program for processing or controlling by the processor 2050, data, or the like. The memory 2040 may include one or more of the memory devices 100, 200, and 300 according to example embodiments, and the processor 2050 may transfer a command to the memory 2040 according to a required operation to thus write data thereto or read data therefrom.

The memory 2040 may be embedded in the electronic device 2000, or may communicate with the processor 2050 via a separate interface. In the case of communicating with the processor 2050 via the separate interface, the processor 2050 may write data to the memory 2040 or read data therefrom via various interface standards such as SD, SDHC, SDXC, MICRO SD, USB, and the like.

The processor 2050 may control operations of respective parts included in the electronic device 2000. The processor 2050 may perform controlling and processing relevant to voice communications, video communications, data communications, and the like, or may also perform controlling and processing for multimedia playback and management. In addition, the processor 2050 may process an input transferred through the input unit 2020 by a user, and may output the result thereof via the output unit 2030. In addition, the processor 2050 may write data required to control operations of the electronic device 2000 to the memory 2040 or read data therefrom.

As set forth above, with a memory device according to example embodiments of inventive concepts, a cover layer may be disposed above a peripheral circuit device, and a peripheral contact may be separated from the cover layer above a planar gate electrode layer. Since the cover layer is not etched during a process of forming the peripheral contact, the peripheral contact and a cell contact may be formed in a single process. Thus, a process of manufacturing a memory device may be simplified and manufacturing costs may be reduced.

It should be understood that example embodiments described herein should be considered in a descriptive sense only and not for purposes of limitation. Descriptions of features or aspects within each device or method according to example embodiments should typically be considered as available for other similar features or aspects in other devices or methods according to example embodiments. While some example embodiments have been shown and described above, it will be apparent to those skilled in the art that modifications and variations could be made without departing from the scope of the claims.

1. A memory device comprising:
a substrate including a cell region and a peripheral circuit region;
a plurality of gate electrode layers stacked on top of each other on the substrate;
a channel region on the cell region of the substrate, the channel region extending through the gate electrode layers in a direction perpendicular to an upper surface of the substrate;
a plurality of cell contacts connected to the plurality of gate electrode layers;
an active region on the peripheral circuit region of the substrate;
a plurality of planar gate electrode layers on the peripheral circuit region and adjacent to the active region;
a cover layer on the active region; and
a plurality of peripheral contacts connected to the active region and the plurality of planar gate electrode layers,
at least a portion of the plurality of peripheral contacts is separated from the cover layer above the plurality of planar gate electrode layers.

2. The memory device of claim 1, wherein the plurality of peripheral contacts include:
a plurality of first peripheral contacts connected to the planar gate electrode layers; and
a plurality of second peripheral contacts connected to the active region.

3. The memory device of claim 2, wherein
the plurality of first peripheral contacts are separated from the cover layer, and
the plurality of second peripheral contacts penetrate through the cover layer and contact the active region.

4. The memory device of claim 2, further comprising:
a planar gate spacer on the peripheral circuit region between the plurality of planar gate electrode layers and the cover layer, wherein
the plurality of first peripheral contacts penetrate through the planar gate spacer and connect to the plurality of planar gate electrode layers.

5. The memory device of claim 1, further comprising:
an interlayer insulating layer on the substrate over the cell region and the peripheral circuit region.

6. The memory device of claim 5, wherein the interlayer insulating layer is on the cover layer.

7. The memory device of claim 5, wherein the interlayer insulating layer includes:
a first interlayer insulating layer covering the active region and the plurality of planar gate electrode layers, and
a second interlayer insulating layer on the first interlayer insulating layer.

8. The memory device of claim 7, wherein at least a portion of the cover layer is between the first interlayer insulating layer and the second interlayer insulating layer.

9. The memory device of claim 1, wherein at least a portion of the cover layer extends along a side of the planar gate electrode layers.

10. A memory device comprising:
a substrate;
a plurality of gate electrode layers stacked on top of each other on the substrate;
a plurality of channel regions on the substrate, the channel regions extending through the plurality of gate electrode layers in a direction perpendicular to an upper surface of the substrate;
a plurality of peripheral circuit devices on the substrate,
the peripheral circuit devices adjacent to the plurality of gate electrodes layers,
the peripheral circuit devices including an active region and a plurality of planar gate electrode layers adjacent to the active region;
a plurality of cell contacts connected to the plurality of gate electrode layers;
a plurality of first peripheral contacts connected to the plurality of planar gate electrode layers; and
a cover layer on the plurality of peripheral circuit devices, the cover layer contacts with the second peripheral contacts on the active region, and does not contacts with the first peripheral contacts on the planar gate electrode layers.

11-15. (canceled)

16. A memory device comprising:
a substrate including a cell region and a peripheral circuit region;
a memory cell array on the cell region, the memory cell array including a plurality of memory cell strings that each include a plurality of memory cells stacked on top of each other between a ground selection transistor and a string selection transistor;
a plurality of cell contacts connected to the memory cell strings;
an active region in the peripheral circuit region;
at least one planar transistor on the peripheral circuit region, each planar transistor including a gate electrode on a gate insulating layer that is adjacent to the active region;
a spacer covering sidewalls of the gate electrode and gate insulating layer of the at least one planar transistor;
a cover layer on the peripheral circuit region, the cover layer covering the active region, the cover layer including an open region that exposes a top surface of the gate electrode of the at least one planar transistor;
an interlayer insulating layer on the memory cell array and the cover layer; and
a plurality of peripheral contacts connected to the active region and the gate electrode of the least one planar transistor, the plurality of peripheral contacts extending through the interlayer insulating layer and separating from the conver layer in the open region.

17. The memory device of claim 16, wherein the at least one planar transistor is a plurality of planar transistors on the peripheral circuit region,
each pair of the planar transistors are connected to each other by the active region, and
the plurality of peripheral contacts includes a plurality of first peripheral contacts connected to the gate electrodes of the plurality of planar transistors and a plurality of second peripheral contacts connected to the active region.

18. The memory device of claim 16, wherein the spacer covers the active region.

19. The memory device of claim 16, wherein
the plurality of cell contacts extend through the interlayer insulating layer,
a material of the cover layer is a different material than a material of the spacer, and
the material of the cover layer has an etch selectivity with respect to the material of the spacer.

20. The memory device of claim 16, wherein the cover layer is spaced apart from a top surface of the substrate over the peripheral circuit region and at least one planar transistor.
